(19) United States
(12) Patent Application Publication
(10) Pub. No.: US 2015/0333280 A1
(43) Pub. Date: Nov. 19, 2015

(54) Metal Complexes

(71) Applicant: MERCK PATENT GMBH, Darmstadt (DE)

(72) Inventors: Philipp Stoessel, Frankfurt Am Main (DE); Nils Koenen, Darmstadt (DE); Esther Breuning, Ober-Ramstadt (DE); Christian Ehrenreich, Darmstadt (DE)

(73) Assignee: MERCK PATENT GMBH, Darmstadt (DE)

(21) Appl. No.: 14/654,187

(22) PCT Filed: Nov. 27, 2013
(86) PCT No.: PCT/EP2013/003581

§ 371 Date: Jun. 19, 2015

(30) Foreign Application Priority Data
Dec. 21, 2012 (EP) 12008582.4
Jul. 10, 2013 (EP) 13003484.6

(51) Int. Cl. H01L 51/00; C07F 15/00; C09K 11/02; C09K 11/06

(52) U.S. Cl. CPC H01L 51/0085; C09K 11/06; C07F 15/0033; C09K 11/025; C09K 2211/1044; C09K 2211/185; C09K 2211/1007; H01L 51/5012

(57) ABSTRACT

The present invention relates to metal complexes and to electronic devices, in particular organic electroluminescent devices, comprising these metal complexes.

The present invention relates to metal complexes and to electronic devices, in particular organic electroluminescent devices, comprising these metal complexes.

For organic electroluminescent devices (OLEDs) in which organic semiconductors are employed as functional materials, the emitting materials employed are increasingly organometallic complexes which exhibit phosphorescence instead of fluorescence. For quantum-mechanical reasons, an up to four-fold increase in the energy and power efficiency is possible using organometallic compounds as phosphorescence emitters. In general, however, there is still a need for improvement in OLEDs which exhibit triplet emission, in particular with respect to efficiency, operating voltage and lifetime.

In accordance with the prior art, the triplet emitters employed in phosphorescent OLEDs are, in particular, iridium complexes. WO 2011/044988 discloses iridium complexes in which the ligand contains at least one carbonyl group. In general, further improvements are desirable in the case of phosphorescent emitters.

The object of the present invention is therefore the provision of novel metal complexes which are suitable as emitters for use in OLEDs and at the same time result in improved properties of the OLED, in particular with respect to efficiency, operating voltage, lifetime, emission colour and/or thermal stability of the luminescence.

Surprisingly, it has been found that certain metal chelate complexes described in greater detail below which contain an additional nitrogen atom in certain positions in the ligand achieve this object and exhibit improved properties in organic electroluminescent devices. The incorporation of the nitrogen atom enables the emission colour of the compound to be adjusted selectively very well. In particular, it is also possible with these metal complexes, depending on the position of the nitrogen atom, to obtain blue emission with very good emission properties. The present invention therefore relates to these metal complexes and to electronic devices, in particular organic electroluminescent devices, which comprise these complexes.

The invention thus relates to a compound of the formula (1),

[Ir(L)ₙ(L′)ₘ] formula (1)

where the compound of the general formula (1) contains a moiety Ir(L)ₙ of the formula (2):

where the following applies to the symbols and indices used:
Z is on each occurrence CR or N, with the proviso that precisely one group Z stands for N and the other group Z stands for CR;
Y is on each occurrence, identically or differently, CR or N, with the proviso that a maximum of one symbol Y stands for N, or two adjacent symbols Y together stand for a group of the following formula (3),

where the dashed bonds symbolise the linking of this group in the ligand;
X is on each occurrence, identically or differently, CR or N, with the proviso that a maximum of two symbols X per ligand stand for N;
R is on each occurrence, identically or differently, H, D, F, Cl, Br, I, N(R¹)₂, CN, Si(R¹)₃, B(OR¹)₂, C(═O)R¹, a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which may be substituted by one or more radicals R¹, where one or more non-adjacent CH₂ groups may be replaced by R¹C═CR¹, Si(R¹)₂, C═O, NR¹, O, S or CONR¹ and where one or more H atoms may be replaced by D, F or CN, or an aromatic or heteroaromatic ring system having 5 to 60 aromatic ring atoms, which may in each case be substituted by one or more radicals R¹, or an aryloxy or heteroaryloxy group having 5 to 60 aromatic ring atoms, which may be substituted by one or more radicals R¹, or a diarylamino group, diheteroarylamino group or arylheteroarylamino group having 10 to 40 aromatic ring atoms, which may be substituted by one or more radicals R¹; two or more adjacent radicals R here may also form a mono- or polycyclic, aliphatic, aromatic and/or benzo-fused ring system with one another;
R¹ is on each occurrence, identically or differently, H, D, F, N(R²)₂, CN, Si(R²)₃, B(OR²)₂, C(═O)R², a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which may be substituted by one or more radicals R², where one or more non-adjacent CH₂ groups may be replaced by R²C═CR², Si(R²)₂, C═O, NR², O, S or CONR² and where one or more H atoms may be replaced by D, F or CN, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which may be substituted by one or more radicals R², or a diarylamino group, diheteroarylamino group or arylheteroarylamino group having 10 to 40 aromatic ring atoms, which may be substituted by one or more radicals R²; two or more adjacent radicals R¹ here may form a mono- or polycyclic, aliphatic ring system with one another;
R² is on each occurrence, identically or differently, H, D, F or an aliphatic, aromatic and/or heteroaromatic organic radical having 1 to 20 C atoms, in particular a hydrocarbon radical, in which, in addition, one or more H atoms may be replaced by D or F; two or more substituents R² here may also form a mono- or polycyclic, aliphatic or aromatic ring system with one another;
L′ is, identically or differently on each occurrence, a mono- or bidentate ligand;
n is 1, 2 or 3;
m is 0, 1, 2, 3 or 4.

The indices n and m here are selected so that the coordination number at the iridium corresponds in total to 6. This is dependent, in particular, on how many ligands L are present and whether the ligands L′ are mono- or bidentate ligands.

In the following description, “adjacent groups X” means that the groups X are bonded directly to one another in the structure.

Furthermore, “adjacent” in the definition of the radicals means that these radicals are bonded to the same C atom or to C atoms which are bonded directly to one another or, if they are not bonded to directly bonded C atoms, they are bonded in the next-possible position in which a substituent can be bonded. This is explained again with reference to a specific ligand in the following diagrammatic representation of adjacent radicals:

An aryl group in the sense of this invention contains 6 to 40 C atoms; a heteroaryl group in the sense of this invention contains 2 to 40 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed aryl or heteroaryl group, for example naphthalene, anthracene, phenanthrene, quinoline, isoquinoline, etc.

An aromatic ring system in the sense of this invention contains 6 to 60 C atoms in the ring system. A heteroaromatic ring system in the sense of this invention contains 2 to 60 C atoms and at least one heteroatom in the ring system, with the proviso that the sum of C atoms and heteroatoms is at least 5. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit (preferably less than 10% of the atoms other than H), such as, for example, an sp³-hybridised C, N or O atom or a carbonyl group. Thus, for example, systems such as 9,9′-spirobifluorene, 9,9-diarylfluorene, triarylamine, diaryl ether, stilbene, etc., are also intended to be taken to be aromatic ring systems in the sense of this invention, as are systems in which two or more aryl groups are interrupted, for example, by a linear or cyclic alkylene group or by a silylene group.

A cyclic alkyl, alkoxy or thioalkoxy group in the sense of this invention is taken to mean a monocyclic, bicyclic or polycyclic group.

For the purposes of the present invention, a C₁- to C₄₀-alkyl group, in which, in addition, individual H atoms or CH₂ groups may be substituted by the above-mentioned groups, is taken to mean, for example, the radicals methyl, ethyl, n-propyl, i-propyl, n-butyl, i-butyl, s-butyl, t-butyl, 2-methylbutyl, n-pentyl, s-pentyl, tert-pentyl, 2-pentyl, neopentyl, cyclopentyl, n-hexyl, s-hexyl, tert-hexyl, 2-hexyl, 3-hexyl, cyclohexyl, 2-methylpentyl, neohexyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, trifluoromethyl, pentafluoroethyl or 2,2,2-trifluoroethyl. An alkenyl group is taken to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is taken to mean, for example, ethynyl, propynyl, butynyl, pentynyl, hexynyl, heptynyl or octynyl. A C₁- to C₄₀-alkoxy group is taken to mean, for example, methoxy, trifluoromethoxy, ethoxy, n-propoxy, i-propoxy, n-butoxy, i-butoxy, s-butoxy, t-butoxy or 2-methylbutoxy. An aromatic or heteroaromatic ring system having 5-60 aromatic ring atoms, which may also in each case be substituted by the above-mentioned radicals R and which may be linked to the aromatic or heteroaromatic ring system via any desired positions, is taken to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The complexes according to the invention can be facial or pseudofacial, or they can be meridional or pseudomeridional.

In a preferred embodiment, the index n=3, i.e. the metal complex is homoleptic, and the index m=0.

In a further preferred embodiment, the index n=2 and m=1, and the complex according to the invention contains two ligands L and one bidentate ligand L′. It is preferred here for the ligand L′ to be a ligand which is coordinated to the iridium via one carbon atom and one nitrogen atom, two oxygen atoms, two nitrogen atoms, one oxygen atom and one nitrogen atom or one carbon atom and one oxygen atom.

In a further preferred embodiment, the index n=1 and m=2, and the complex according to the invention contains one ligand L and two bidentate ligands L′. This is preferred, in particular, if the ligand L′ is an ortho-metallated ligand which is coordinated to the iridium via one carbon atom and one nitrogen atom or one carbon atom and one oxygen atom.

As described above, a group Z in the structural unit of the formula (2) stands for N. Embodiments of the formula (2) are thus the following formulae (4) and (5),

where the symbols and indices used have the meanings given above.

A hypsochromic shift in the emission colour is observed in the case of moieties of the formula (4), while a bathochromic shift in the emission colour is observed in the case of moieties of the formula (5), in each case compared with structures in accordance with the prior art which contain a carbon atom instead of the nitrogen atom, but otherwise have the same structure and the same substitution pattern.

In a further preferred embodiment of the invention, the compounds according to the invention contain a maximum of one group of the formula (3). They are thus preferably compounds of the following formulae (6), (7) and (8),

where Y stands on each occurrence, identically or differently, for CR or N, and the other symbols and indices have the meanings given above.

Preferred embodiments of the formulae (6) to (8) are the structures of the following formulae (6a), (6b), (7a), (7b), (8a) and (8b),

where Y stands on each occurrence, identically or differently, for CR or N, and the other symbols and indices have the meanings given above.

In a further preferred embodiment of the invention, a total of 0, 1 or 2 of the symbols Y and, if present, X in the ligand L stand for N. Particularly preferably, a total of 0 or 1 of the symbols Y and, if present, X in the ligand L stand for N. Very particularly preferably, none of the symbols Y and, if present, X stand for N, i.e. the symbols Y stand, identically or differently on each occurrence, for CR and/or two adjacent symbols Y together stand for a group of the formula (3), where X stands for CR. Especially preferably, all symbols Y stand, identically or differently on each occurrence, for CR.

Preferred embodiments of the formula (6) are the structures of the following formulae (6-1) to (6-5), preferred embodiments of the formula (7) are the structures of the following formulae (7-1) to (7-7), and preferred embodiments of the formula (8) are the structures of the following formulae (8-1) to (8-7),

where the symbols and indices used have the meanings given above.

Preferred embodiments of the formulae (6-1) to (6-5), (7-1) to (7-7) and (8-1) to (8-7) are the structures of the following formulae (6a-1) to (6b-5), (7a-1) to (7b-7) and (8a-1) to (8b-7),

where the symbols and indices used have the meanings given above.

In the above-mentioned structures, the radical R which is bonded in the ortho-position to the coordination to the iridium is preferably selected from the group consisting of H, D, F and methyl. This applies, in particular, in the case of facial, homoleptic complexes, while in the case of meridional or heteroleptic complexes, other radicals R may also be preferred in this position.

In a further embodiment of the invention, it is preferred for a group R which is not equal to hydrogen or deuterium to be bonded as substituent adjacent to the atom Z in the moiety of the formula (2) which stands for a nitrogen atom.

It is furthermore preferred, if one or more groups Y and/or, if present, X in the moieties of the formula (2) stand for N, for a group R which is not equal to hydrogen or deuterium to be bonded as substituent adjacent to this nitrogen atom.

The ligand L preferably contains a group R which is not equal to hydrogen or deuterium bonded as substituent adjacent to all atoms Z, Y and, if present, X which stand for a nitrogen atom.

This substituent R is preferably a group selected from CF₃, OCF₃, alkyl or alkoxy groups having 1 to 10 C atoms, in particular branched or cyclic alkyl or alkoxy groups having 3 to 10 C atoms, a dialkylamino group having 2 to 10 C atoms, aromatic or heteroaromatic ring systems or aralkyl or heteroaralkyl groups. These groups are bulky groups. Furthermore, this radical R can preferably also form a ring with an adjacent radical R. These are then preferably structures of the formulae (9) to (15), as described in greater detail below.

If the radical R which is adjacent to a nitrogen atom stands for an alkyl group, this alkyl group then preferably has 3 to 10 C atoms. It is furthermore preferably a secondary or tertiary alkyl group in which the secondary or tertiary C atom is either bonded directly to the ligand or is bonded to the ligand via a CH₂ group. This alkyl group is particularly preferably selected from the structures of the following formulae (R-1) to (R-33), where in each case the linking of these groups to the ligand is also drawn in:

where Lig denotes the linking of the alkyl group to the ligand.

If the radical R which is adjacent to a nitrogen atom stands for an alkoxy group, this alkoxy group then preferably has 3 to 10 C atoms. This alkoxy group is preferably selected from the structures of the following formulae (R-34) to (R-47), where in each case the linking of these groups to the ligand is also drawn in:

where Lig denotes the linking of the alkoxy group to the ligand.

If the radical R which is adjacent to a nitrogen atom stands for a dialkylamino group, each of these alkyl groups then preferably has 1 to 8 C atoms, particularly preferably 1 to 6 C atoms. Examples of suitable alkyl groups are methyl, ethyl or the structures shown above as groups (R-1) to (R-33). The dialkylamino group is particularly preferably selected from the structures of the following formulae (R-48) to (R-55), where in each case the linking of these groups to the ligand is also drawn in:

where Lig denotes the linking of the dialkylamino group to the ligand.

If the radical R which is adjacent to a nitrogen atom stands for an aralkyl group, this aralkyl group is then preferably selected from the structures of the following formulae (R-56) to (R-69), where in each case the linking of these groups to the ligand is also drawn in:

where Lig denotes the linking of the aralkyl group to the ligand, and the phenyl groups may in each case be substituted by one or more radicals R¹.

If the radical R which is adjacent to a nitrogen atom stands for an aromatic or heteroaromatic ring system, this aromatic or heteroaromatic ring system then preferably has 5 to 30 aromatic ring atoms, particularly preferably 5 to 24 aromatic ring atoms. This aromatic or heteroaromatic ring system furthermore preferably contains no aryl or heteroaryl groups in which more than two aromatic six-membered rings are condensed directly onto one another. The aromatic or heteroaromatic ring system particularly preferably contains no condensed aryl or heteroaryl groups at all, and it very particularly preferably contains only phenyl groups. The aromatic ring system here is preferably selected from the structures of the following formulae (R-70) to (R-88), where in each case the linking of these groups to the ligand is also drawn in:

where Lig denotes the linking of the aromatic ring system to the ligand, and the phenyl groups may in each case be substituted by one or more radicals R¹.

Furthermore, the heteroaromatic ring system is preferably selected from the structures of the following formulae (R-89) to (R-119), where in each case the linking of these groups to the ligand is also drawn in:

where Lig denotes the linking of the heteroaromatic ring system to the ligand, and the aromatic and heteroaromatic groups may in each case be substituted by one or more radicals R¹.

It is furthermore preferred for two adjacent groups Y and/or, if present, two adjacent groups X in the moiety of the formula (2) to stand for CR and for the respective radicals R, together with the C atoms, to form a condensed-on aliphatic 5-membered ring, 6-membered ring or 7-membered ring without acidic benzylic protons and/or for two radicals R which are bonded to C atoms bonded directly to one another in the moieties of the formulae (6-1) to (8-7) or the preferred embodiments, together with the C atoms to which they are bonded, to form with one another a condensed-on aliphatic 5-membered ring, 6-membered ring or 7-membered ring without acidic benzylic protons. Aliphatic here means that the ring does not form a common electron system with the aromatic structure of the ligand L and thus does not form a single enlarged condensed heteroaromatic system, but instead the Tr-system of the ligand does not extend further over the condensed-on group. However, this does not exclude the condensed-on group itself containing unsaturated or aromatic groups, so long as they are not connected directly to the electron system of the ligand basic structure.

The condensed-on aliphatic ring formed in this way preferably has a structure of one of the following formulae (9) to (15),

where R¹ and R² have the meanings given above, where a plurality of R¹ may also be linked to one another and thus may form a further ring system, the dashed bonds indicate the linking of the two carbon atoms in the ligand, and furthermore:
A¹, A³ are, identically or differently on each occurrence, C(R³)₂, O, S, NR³ or C(═O);
A² is, identically or differently on each occurrence, C(R¹)₂, O, S, NR³ or C(═O); or A²-A² in formula (10), (11), (13), (14) or (15) may, apart from a combination of the above-mentioned groups, stand for —CR²═CR²— or an ortho-linked arylene or heteroarylene group having 5 to 14 aromatic ring atoms, which may be substituted by one or more radicals R²;
G is an alkylene group having 1, 2 or 3 C atoms, which may be substituted by one or more radicals R², —CR²═CR²— or an ortho-linked arylene or heteroarylene group having 5 to 14 aromatic ring atoms, which may be substituted by one or more radicals R²;
R³ is, identically or differently on each occurrence, F, a straight-chain alkyl or alkoxy group having 1 to 10 C atoms, a branched or cyclic alkyl or alkoxy group having 3 to 10 C atoms, each of which may be substituted by one or more radicals R², where one or more non-adjacent CH₂ groups may be replaced by R²C═CR², C═C, Si(R²)₂, C═O, NR², O, S or CONR² and where one or more H atoms may be replaced by D or F, or an aromatic or heteroaromatic ring system having 5 to 24 aromatic ring atoms, which may in each case be substituted by one or more radicals R², or an aryloxy or heteroaryloxy group having 5 to 24 aromatic ring atoms, which may be substituted by one or more radicals R², or an aralkyl or heteroaralkyl group having 5 to 24 aromatic ring atoms, which may be substituted by one or more radicals R²; two radicals R³ here which are bonded to the same carbon atom may form an aliphatic or aromatic ring system with one another and thus form a spiro system; furthermore, R³ may form an aliphatic ring system with an adjacent radical R or R¹;
   with the proviso that two heteroatoms in these groups are not bonded directly to one another and two groups C═O are not bonded directly to one another.

Furthermore, it may also be preferred for two adjacent groups Y and/or, if present, two adjacent groups X in the moiety of the formula (2) to stand for CR and for the respective radicals R, together with the C atoms, to form a 5-, 6- or 7-membered ring other than that of the above-mentioned formulae (9) to (15).

The groups of the formulae (9) to (15) may be present in any position of the moiety of the formula (2) in which two groups Y or, if present, two groups X are bonded directly to one another. Preferred positions in which a group of the formulae (9) to (15) is present are the moieties of the following formulae (6′) to (8″″),

where the symbols and indices used have the meanings given above, and * in each case indicates the position at which the two adjacent groups Y or X stand for CR and the respective radicals R, together with the C atoms, form a ring of one of the above-mentioned formulae (9) to (15).

In the structures of the formulae (9) to (15) depicted above and the further embodiments of these structures mentioned as preferred, a double bond is formally shown between the two carbon atoms. This represents a simplification of the chemical structure if these two carbon atoms are bonded into an aromatic or heteroaromatic system and the bond between these two carbon atoms is thus formally between the bond order of a single bond and that of a double bond. The drawing-in of the formal double bond should thus not be interpreted as limiting for the structure, but instead it is apparent to the person skilled in the art that this is an aromatic bond if this is bonded into an aromatic or heteroaromatic system.

It is essential in the groups of the formulae (9) to (15) that these do not contain any acidic benzylic protons. Benzylic protons are taken to mean protons which are bonded to a carbon atom which is bonded directly to the ligand. The absence of acidic benzylic protons is achieved in the formulae (9) to (11) and (15) through A¹ and A³, if they stand for C(R³)₂, being defined in such a way that R³ is not equal to hydrogen. The absence of acidic benzylic protons is achieved in formulae (12) to (15) through it being a bicyclic structure. Owing to the rigid spatial arrangement, R¹, if it stands for H, is usually significantly less acidic than benzylic protons, since the corresponding anion of the bicyclic structure is not mesomerism-stabilised. Even if R¹ in formulae (12) to (15) stands for H, this is therefore a nonacidic proton in the sense of the present application.

In a preferred embodiment of the structure of the formulae (9) to (15), a maximum of one of the groups A¹, A² and A³ stands for a heteroatom, in particular for O or NR³, and the other groups stand for C(R³)₂ or C(R¹)₂, or A¹ and A³ stand, identically or differently on each occurrence, for O or NR³ and A² stands for C(R¹)₂. In a particularly preferred embodiment of the invention, A¹ and A³ stand, identically or differently on each occurrence, for C(R³)₂ and A² stands for C(R¹)₂ and particularly preferably for C(R³)₂ or CH₂. Preferred embodiments of the formula (9) are thus the structures of the formulae (9-A), (9-B), (9-C) and (9-D), and particularly preferred embodiment of the formula (9-A) are the structures of the formulae (9-E) and (9-F),

where R¹ and R³ have the meanings given above, and A¹, A² and A³ stand, identically or differently on each occurrence, for O or NR³.

Preferred embodiments of the formula (10) are the structures of the following formulae (10-A) to (10-F),

where R¹ and R³ have the meanings given above, and A¹, A² and A³ stand, identically or differently on each occurrence, for O or NR³.

Preferred embodiments of the formula (11) are the structures of the following formulae (11-A) to (11-E),

where R¹ and R³ have the meanings given above, and A¹, A² and A³ stand, identically or differently on each occurrence, for O or NR³.

In a preferred embodiment of the structure of the formula (12), the radicals R¹ which are bonded to the bridgehead stand for H, D, F or CH₃. A² furthermore preferably stands for C(R¹)₂ or O, and particularly preferably for C(R³)₂. Preferred embodiments of the formula (12) are thus the structures of the formulae (12-A) and (12-B), and a particularly preferred embodiment of the formula (12-A) is a structure of the formula (12-C),

where the symbols used have the meanings given above.

In a preferred embodiment of the structure of the formulae (13), (14) and (15), the radicals R¹ which are bonded to the bridgehead stand for H, D, F or CH₃, particularly preferably for H. A² furthermore preferably stands for C(R¹)₂. Preferred embodiments of the formulae (13), (14) and (15) are thus the structures of the formulae (13-A), (14-A) and (15-A),

where the symbols used have the meanings given above.

The group G in the formulae (12), (12-A), (12-B), (12-C), (13), (13-A), (14), (14-A), (15) and (15-A) furthermore preferably stands for a 1,2-ethylene group, which may be substituted by one or more radicals R², where R² preferably stands, identically or differently on each occurrence, for H or an alkyl group having 1 to 4 C atoms, or an ortho-arylene group having 6 to 10 C atoms, which may be substituted by one or more radicals R², but is preferably unsubstituted, in particular an ortho-phenylene group, which may be substituted by one or more radicals R², but is preferably unsubstituted.

In a further preferred embodiment of the invention, R³ in the groups of the formulae (9) to (15) and in the preferred embodiments stands, identically or differently on each occurrence, for F, a straight-chain alkyl group having 1 to 10 C atoms or a branched or cyclic alkyl group having 3 to 20 C atoms, where in each case one or more non-adjacent CH₂ groups may be replaced by R²C═CR² and one or more H atoms may be replaced by D or F, or an aromatic or heteroaromatic ring system having 5 to 14 aromatic ring atoms, which may in each case be substituted by one or more radicals R²; two radicals R³ here which are bonded to the same carbon atom may form an aliphatic or aromatic ring system with one another and thus form a spiro system; furthermore, R³ may form an aliphatic ring system with an adjacent radical R or R¹.

In a particularly preferred embodiment of the invention, R³ in the groups of the formulae (9) to (15) and in the preferred embodiments stands, identically or differently on each occurrence, for F, a straight-chain alkyl group having 1 to 3 C atoms, in particular methyl, or an aromatic or heteroaromatic ring system having 5 to 12 aromatic ring atoms, each of which may be substituted by one or more radicals R², but is preferably unsubstituted; two radicals R³ here which are bonded to the same carbon atom may form an aliphatic or aromatic ring system with one another and thus form a Spiro system; furthermore, R³ may form an aliphatic ring system with an adjacent radical R or R¹.

Examples of particularly suitable groups of the formula (9) are the groups shown below:

Examples of particularly suitable groups of the formula (10) are the groups shown below:

Examples of particularly suitable groups of the formulae (11), (14) and (15) are the groups shown below:

Examples of particularly suitable groups of the formula (12) are the groups shown below:

Examples of particularly suitable groups of the formula (13) are the groups shown below:

In particular, the use of condensed-on bicyclic structures of this type may also result in chiral ligands L owing to the chirality of the structures. Both the use of enantiomerically pure ligands and also the use of the racemate may be suitable here. It may also be suitable, in particular, to use not only one enantiomer of a ligand in the metal complex according to the invention, but intentionally both enantiomers, so that, for example, a complex (+L)₂(−L)M or a complex (+L)(−L)₂M forms, where +L or −L in each case denotes the corresponding + or − enantiomer of the ligand. This may have advantages with respect to the solubility of the corresponding complex compared with complexes which contain only +L or only −L as ligand.

If further or other radicals R are bonded in the moiety of the formula (2), these radicals R are preferably selected on each occurrence, identically or differently, from the group consisting of H, D, F, N(R¹)₂, CN, Si(R¹)₃, C(═O)R¹, a straight-chain alkyl group having 1 to 10 C atoms or an alkenyl group having 2 to 10 C atoms or a branched or cyclic alkyl group having 3 to 10 C atoms, each of which may be substituted by one or more radicals R¹, where one or more H atoms may be replaced by D or F, or an aromatic or heteroaromatic ring system having 5 to 24 aromatic ring atoms, which may in each case be substituted by one or more radicals R¹; two adjacent radicals R or R with R¹ here may also form a mono- or polycyclic, aliphatic or aromatic ring system with one another. These radicals R are particularly preferably selected on each occurrence, identically or differently, from the group consisting of H, D, F, a straight-chain alkyl group having 1 to 6 C atoms or a branched or cyclic alkyl group having 3 to 10 C atoms, where one or more H atoms may be replaced by F, or an aromatic or heteroaromatic ring system having 5 to 18 aromatic ring atoms, which may in each case be substituted by one or more radicals R¹; two adjacent radicals R or R with R¹ here may also form a mono- or polycyclic, aliphatic or aromatic ring system with one another. In the case of an aromatic or heteroaromatic ring system, it is preferred for this to have not more than two aromatic 6-membered rings condensed directly onto one another, in particular absolutely no aromatic 6-membered rings condensed directly onto one another.

Preferred ligands L′, as can occur in compounds of the formula (1), are described below. The ligands L′ are by definition mono- or bidentate ligands. The ligands L′ are preferably neutral, monoanionic, dianionic or trianionic ligands, particularly preferably neutral or monoanionic ligands. Preference is given to bidentate ligands L′.

Preferred neutral, monodentate ligands L′ are selected from carbon monoxide, nitrogen monoxide, alkyl cyanides, such as, for example, acetonitrile, aryl cyanides, such as, for example, benzonitrile, alkyl isocyanides, such as, for example, methyl isonitrile, aryl isocyanides, such as, for example, benzoisonitrile, amines, such as, for example, trimethylamine, triethylamine, morpholine, phosphines, in particular halophosphines, trialkylphosphines, triarylphosphines or alkylarylphosphines, such as, for example, trifluorophosphine, trimethylphosphine, tricyclohexylphosphine, tri-tert-butylphosphine, triphenylphosphine, tris(pentafluorophenyl)phosphine, phosphites, such as, for example, trimethyl phosphite, triethyl phosphite, arsines, such as, for example, trifluoroarsine, trimethylarsine, tricyclohexylarsine, tri-tert-butylarsine, triphenylarsine, tris(pentafluorophenyl)arsine, stibines, such as, for example, trifluorostibine, trimethylstibine, tricyclohexylstibine, tri-tert-butylstibine, triphenylstibine, tris(pentafluorophenyl)stibine, nitrogen-containing heterocycles, such as, for example, pyridine, pyridazine, pyrazine, pyrimidine, triazine, and carbenes, in particular Arduengo carbenes.

Preferred monoanionic, monodentate ligands L′ are selected from hydride, deuteride, the halides F⁻, Cl⁻, Br⁻ and I⁻, alkylacetylides, such as, for example, methyl-C≡C⁻, tert-butyl-C≡C⁻, arylacetylides, such as, for example, phenyl-C≡C⁻, cyanide, cyanate, isocyanate, thiocyanate, isothiocyanate, aliphatic or aromatic alcoholates, such as, for example, methanolate, ethanolate, propanolate, isopropanolate, tert-butylate, phenolate, aliphatic or aromatic thioalcoholates, such as, for example, methanethiolate, ethanethiolate, propanethiolate, isopropanethiolate, tert-thiobutylate, thiophenolate, amides, such as, for example, dimethylamide, diethylamide, diisopropylamide, morpholide, carboxylates, such as, for example, acetate, trifluoroacetate, propionate, benzoate, aryl groups, such as, for example, phenyl, naphthyl, and anionic, nitrogen-containing heterocycles, such as pyrrolide, imidazolide, pyrazolide. The alkyl groups in these groups are preferably C₁-C₂₀-alkyl groups, particularly preferably C₁-C₁₀-alkyl groups, very particularly preferably C₁-C₄-alkyl groups. An aryl group is also taken to mean heteroaryl groups. These groups are as defined above.

Preferred di- or trianionic ligands are O²⁻, S²⁻, carbides, which result in coordination in the form R—C≡M, and nitrenes, which result in coordination in the form R—N=M, where R generally stands for a substituent, and N³⁻.

Preferred neutral or mono- or dianionic, bidentate or polydentate ligands L′ are selected from diamines, such as, for example, ethylenediamine, N,N,N′,N′-tetramethylethylenediamine, propylenediamine, N,N,N′,N′-tetramethylpropylenediamine, cis- or trans-diaminocyclohexane, cis- or trans-N,N,N′,N′-tetramethyldiaminocyclohexane, imines, such as, for example, 2-[1-(phenylimino)ethyl]pyridine, 2-[1-(2-methylphenylimino)ethyl]pyridine, 2-[1-(2,6-diisopropylphenylimino)ethyl]pyridine, 2-[1-(methylimino)ethyl]pyridine, 2-[1-(ethylimino)ethyl]pyridine, 2-[1-(isopropylimino)ethyl]pyridine, 2-[1-(tert-butylimino)ethyl]pyridine, diimines, such as, for example, 1,2-bis(methylimino)ethane, 1,2-bis(ethylimino)ethane, 1,2-bis(isopropylimino)ethane, 1,2-bis(tert-butylimino)ethane, 2,3-bis(methylimino)butane, 2,3-bis(ethylimino)butane, 2,3-bis(isopropylimino)butane, 2,3-bis(tert-butylimino)butane, 1,2-bis(phenylimino)ethane, 1,2-bis(2-methylphenylimino)ethane, 1,2-bis(2,6-diisopropylphenylimino)ethane, 1,2-bis(2,6-di-tert-butylphenylimino)ethane, 2,3-bis(phenylimino)butane, 2,3-bis(2-methylphenylimino)butane, 2,3-bis(2,6-diisopropylphenylimino)butane, 2,3-bis(2,6-di-tert-butylphenylimino)butane, heterocycles containing two nitrogen atoms, such as, for example, 2,2′-bipyridine, o-phenanthroline, diphosphines, such as, for example, bis(diphenylphosphino)methane, bis(diphenylphosphino)ethane, bis(diphenylphosphino)propane, bis(diphenylphosphino)butane, bis(dimethylphosphino)methane, bis(dimethylphosphino)ethane, bis(dimethylphosphino)propane, bis(diethylphosphino)methane, bis(diethylphosphino)ethane, bis(diethylphosphino)propane, bis(di-tert-butylphosphino)methane, bis(di-tert-butylphosphino)ethane, bis(tert-butylphosphino)propane, 1,3-diketonates derived from 1,3-diketones, such as, for example, acetylacetone, benzoylacetone, 1,5-diphenylacetylacetone, dibenzoylmethane, bis(1,1,1-trifluoroacetyl)methane, 2,2,6,6-tetramethyl-3,5-heptanedione, 3-ketonates derived from 3-ketoesters, such as, for example, ethyl acetoacetate, carboxylates derived from aminocarboxylic acids, such as, for example, pyridine-2-carboxylic acid, quinoline-2-carboxylic acid, glycine, N,N-dimethylglycine, alanine, N,N-dimethylaminoalanine, salicyliminates derived from salicylimines, such as, for example, methylsalicylimine, ethylsalicylimine, phenylsalicylimine, dialcoholates derived from dialcohols, such as, for example, ethylene glycol, 1,3-propylene glycol, and dithiolates derived from dithiols, such as, for example, 1,2-ethylenedithiol, 1,3-propylenedithiol.

L′ is particularly preferably a bidentate, monoanionic ligand which coordinates to the iridium via two oxygen atoms, nitrogen and oxygen, carbon and nitrogen or carbon and oxygen.

In a further preferred embodiment of the invention, the ligands L′ are bidentate monoanionic ligands L′ which, with the iridium, form a cyclometallated five- or six-membered ring with at least one iridium-carbon bond, in particular a cyclometallated five-membered ring. These are, in particular, ligands as are generally used in the area of phosphorescent metal complexes for organic electroluminescent devices, i.e. ligands of the type phenylpyridine, naphthylpyridine, phenylquinoline, phenylisoquinoline, etc., each of which may be substituted by one or more radicals R. A multiplicity of ligands of this type is known to the person skilled in the art in the area of phosphorescent electroluminescent devices, and he will be able, without inventive step, to select further ligands of this type as ligand L′ for compounds of the formula (1). The combination of two groups, as represented by the following formulae (16) to (43), where one group is bonded via a neutral atom and the other group is bonded via a negatively charged atom, is generally particularly suitable for this purpose. The neutral atom here is, in particular, a neutral nitrogen atom or a carbene carbon atom and the negatively charged atom is, in particular, a negatively charged carbon atom, a negatively charged nitrogen atom or a negatively charged oxygen atom. The ligand L′ can then be formed from the groups of the formulae (16) to (43) by these groups bonding to one another in each case at the position denoted by #. The position at which the groups coordinate to the metal is denoted by *. Furthermore, two adjacent radicals R which are each bonded to the two groups of the formulae (16) to (43) form an aliphatic or aromatic ring system with one another.

The symbols used here have the same meaning as described above, E stands for O, S or CR₂, and preferably a maximum of two symbols X in each group stand for N, particularly preferably a maximum of one symbol X in each group stands for N. Very particularly preferably, all symbols X stand for CR.

In a very particularly preferred embodiment of the invention, the ligand L′ is a monoanionic ligand formed from two of the groups of the formulae (16) to (43), where one of these groups is coordinated to the iridium via a negatively charged carbon atom and the other of these groups is coordinated to the iridium via a neutral nitrogen atom.

It may likewise be preferred for two adjacent symbols X in these ligands to stand for a group of the above-mentioned formulae (9) to (15).

The further preferred radicals R in the structures shown above are defined like the radicals R of the ligand L.

The ligands L and L′ may also be chiral, depending on the structure. This is the case, in particular, if they contain a bicyclic group of the formulae (12) to (15) or if they contain substituents, for example alkyl, alkoxy, dialkylamino or aralkyl groups, which have one or more stereocentres. Since the basic structure of the complex may also be a chiral structure, the formation of diastereomers and a plurality of enantiomer pairs is possible. The complexes according to the invention then encompass both the mixtures of the various diastereomers or the corresponding racemates and also the individual isolated diastereomers or enantiomers.

The compounds according to the invention may also be rendered soluble by suitable substitution, for example by relatively long alkyl groups (about 4 to 20 C atoms), in particular branched alkyl groups, or optionally substituted aryl groups, for example xylyl, mesityl or branched terphenyl or quaterphenyl groups. Compounds of this type are then soluble in adequate concentration in common organic solvents at room temperature in order to enable the complexes to be processed from solution, for example by printing processes.

The preferred embodiments mentioned above can be combined with one another as desired. In a particularly preferred embodiment of the invention, the preferred embodiments mentioned above apply simultaneously.

The compounds can also be employed as chiral, enantiomerically pure complexes which are able to emit circular-polarised light. This may have advantages, since the polarising filter on the device can thus be omitted. In addition, complexes of this type are also suitable for use in security labels, since, besides the emission, they also have the polarisation of the light as an easily readable feature.

The metal complexes according to the invention can in principle be prepared by various processes. However, the processes described below have proven particularly suitable.

The present invention therefore furthermore relates to a process for the preparation of the compounds of the formula (1) according to the invention by reaction of the corresponding free ligands with iridium alkoxides of the formula (44), with iridium ketoketonates of the formula (45), with iridium halides of the formula (46) or with dimeric iridium complexes of the formula (47) or (48),

where the symbols and indices L′, m, n and R¹ have the meanings indicated above, and Hal=F, Cl, Br or I.

It is likewise possible to use iridium compounds which carry both alkoxide and/or halide and/or hydroxyl and also ketoketonate radicals. These compounds may also be charged. Corresponding iridium compounds which are particularly suitable as starting materials are disclosed in WO 2004/085449. [IrCl₂(acac)₂]⁻, for example Na[IrCl₂(acac)₂], is particularly suitable. Further particularly suitable iridium starting materials are iridium(III) tris(acetylacetonate) and iridium(III) tris(2,2,6,6-tetramethyl-3,5-heptane-dionate).

The synthesis can also be carried out by reaction of the ligands L with iridium complexes of the formula [Ir(L′)₂(HOMe)₂]A or [Ir(L′)₂(NCMe)₂]A or by reaction of the ligands L′ with iridium complexes of the formula [Ir(L)₂(HOMe)₂]A or [Ir(L)₂(NCMe)₂]A, where A in each case represents a non-coordinating anion, such as, for example, triflate, tetrafluoroborate, hexafluorophosphate, etc., in dipolar protic solvents, such as, for example, ethylene glycol, propylene glycol, glycerol, diethylene glycol, triethylene glycol, etc.

The synthesis of the complexes is preferably carried out as described in WO 2002/060910 and in WO 2004/085449. Heteroleptic complexes can also be synthesised, for example, in accordance with WO 05/042548. The synthesis here can also be activated, for example, thermally, photochemically and/or by microwave radiation. Furthermore, the synthesis can also be carried out in an autoclave at elevated pressure and/or elevated temperature.

The reactions can be carried out without addition of solvents or melting aids in a melt of the corresponding ligands to be o-metallated. Solvents or melting aids can also be added if necessary. Suitable solvents are protic or aprotic solvents, such as aliphatic and/or aromatic alcohols (methanol, ethanol, isopropanol, t-butanol, etc.), oligo- and polyalcohols (ethylene glycol, 1,2-propanediol, glycerol, etc.), alcohol ethers (ethoxyethanol, diethylene glycol, triethylene glycol, polyethylene glycol, etc.), ethers (di- and triethylene glycol dimethyl ether, diphenyl ether, etc.), aromatic, heteroaromatic and/or aliphatic hydrocarbons (toluene, xylene, mesitylene, chlorobenzene, pyridine, lutidine, quinoline, isoquinoline, tridecane, hexadecane, etc.), amides (DMF, DMAC, etc.), lactams (NMP), sulfoxides (DMSO) or sulfones (dimethyl sulfone, sulfolane, etc.). Suitable melting aids are compounds which are in solid form at room temperature, but melt on warming of the reaction mixture and dissolve the reactants, so that a homogeneous melt forms. Biphenyl, m-terphenyl, triphenylene, 1,2-, 1,3-, 1,4-bisphenoxybenzene, triphenylphosphine oxide, 18-crown-6, phenol, 1-naphthol, hydroquinone, etc., are particularly suitable.

For the processing of the compounds according to the invention from the liquid phase, for example by spin coating or by printing processes, formulations of the compounds according to the invention are necessary. These formulations can be, for example, solutions, dispersions or emulsions. It may be preferred to use mixtures of two or more solvents for this purpose. Suitable and preferred solvents are, for example, toluene, anisole, o-, m- or p-xylene, methyl benzoate, mesitylene, tetralin, veratrol, THF, methyl-THF, THP, chlorobenzene, dioxane, phenoxytoluene, in particular 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents.

The present invention therefore furthermore relates to a formulation comprising a compound according to the invention and at least one further compound. The further compound may be, for example, a solvent, in particular one of the above-mentioned solvents or a mixture of these solvents. However, the further compound may also be a further organic or inorganic compound which is likewise employed in the electronic device, for example a matrix material. Suitable matrix materials are shown below in connection with the organic electroluminescent device. This further compound may also be polymeric.

The complexes of the formula (1) described above or the preferred embodiments indicated above can be used as active component in an electronic device. The present invention therefore furthermore relates to the use of a compound of the formula (1) or according to one of the preferred embodiments in an electronic device. The compounds according to the invention can furthermore be employed for the generation of singlet oxygen, in photocatalysis or in oxygen sensors.

The present invention still furthermore relates to an electronic device comprising at least one compound of the formula (1) or according to one of the preferred embodiments.

An electronic device is taken to mean a device which comprises an anode, a cathode and at least one layer, where this layer comprises at least one organic or organometallic compound. The electronic device according to the invention thus comprises an anode, a cathode and at least one layer which comprises at least one compound of the formula (1) given above. Preferred electronic devices here are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), light-emitting electrochemical cells (LECs) or organic laser diodes (O-lasers), comprising at least one compound of the formula (1) given above in at least one layer. Particular preference is given to organic electroluminescent devices. Active components are generally the organic or inorganic materials which have been introduced between the anode and cathode, for example charge-injection, charge-transport or charge-blocking materials, but in particular emission materials and matrix materials. The compounds according to the invention exhibit particularly good properties as emission material in organic electroluminescent devices. A preferred embodiment of the invention is therefore organic electroluminescent devices.

The organic electroluminescent device comprises cathode, anode and at least one emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers, charge-generation layers and/or organic or inorganic p/n junctions. Interlayers, which have, for example, an exciton-blocking function and/or control the charge balance in the electroluminescent device, may likewise be introduced between two emitting layers. However, it should be pointed out that each of these layers does not necessarily have to be present.

The organic electroluminescent device here may comprise one emitting layer or a plurality of emitting layers. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. A preferred embodiment is three-layer systems, where the three layers exhibit blue, green and orange or red emission (see, for example, WO 2005/011013), or systems which have more than three emitting layers. A further preferred embodiment is two-layer systems, where the two layers exhibit either blue and yellow or cyan and orange emission. Two-layer systems are of particular interest for lighting applications. Embodiments of this type with the compounds according to the invention are particularly suitable, since they frequently exhibit yellow or orange emission. The white-emitting electroluminescent devices can be employed for lighting applications or as backlight for displays or with colour filters as displays.

In a preferred embodiment of the invention, the organic electroluminescent device comprises the compound of the formula (1) or the preferred embodiments indicated above as emitting compound in one or more emitting layers.

If the compound of the formula (1) is employed as emitting compound in an emitting layer, it is preferably employed in combination with one or more matrix materials. The mixture comprising the compound of the formula (1) and the matrix material comprises between 1 and 99% by vol., preferably between 2 and 90% by vol., particularly preferably between 3 and 40% by vol., especially between 5 and 15% by vol., of the compound of the formula (1), based on the entire mixture comprising emitter and matrix material. Correspondingly, the mixture comprises between 99.9 and 1% by vol., preferably between 98 and 10% by vol., particularly preferably between 97 and 60% by vol., in particular between 95 and 85% by vol., of the matrix material or matrix materials, based on the entire mixture comprising emitter and matrix material.

The matrix material employed can in general be all materials which are known for this purpose in accordance with the prior art. The triplet level of the matrix material is preferably the same as or higher than the triplet level of the emitter.

Suitable matrix materials for the compounds according to the invention are ketones, phosphine oxides, sulfoxides and sulfones, for example in accordance with WO 2004/013080, WO 2004/093207, WO 2006/005627 or WO 2010/006680, triarylamines, carbazole derivatives, for example CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example in accordance with WO 2007/063754 or WO 2008/056746, indenocarbazole derivatives, for example in accordance with WO 2010/136109 or WO 2011/000455, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, diazasilole derivatives, for example in accordance with WO 2010/054729, diazaphosphole derivatives, for example in accordance with WO 2010/054730, triazine derivatives, for example in accordance with WO 2010/015306, WO 2007/063754 or WO 2008/056746, zinc complexes, for example in accordance with EP 652273 or WO 2009/062578, beryllium complexes, dibenzofuran derivatives, for example in accordance with WO 2009/148015, or bridged carbazole derivatives, for example in accordance with US 2009/0136779, WO 2010/050778, WO 2011/042107 or WO 2011/088877, or triphenylene derivatives, for example in accordance with WO 2012/048781.

It may also be preferred to employ a plurality of different matrix materials as a mixture. Suitable for this purpose are, in particular, mixtures of at least one electron-transporting matrix material and at least one hole-transporting matrix material or mixtures of at least two electron-transporting matrix materials or mixtures of at least one hole- or electron-transporting matrix material and at least one further material having a large band gap, which is thus substantially electrically inert and does not participate or does not participate to a significant extent in charge transport, as described, for example, in WO 2010/108579. A preferred combination is, for example, the use of an aromatic ketone or a triazine derivative with a triarylamine derivative or a carbazole derivative as mixed matrix for the metal complex according to the invention.

It is furthermore preferred to employ a mixture of two or more triplet emitters together with a matrix. The triplet emitter having the shorter-wave emission spectrum serves as co-matrix for the triplet-emitter having the longer-wave emission spectrum. Thus, for example, blue- or green-emitting triplet emitters can be employed as co-matrix for the complexes of the formula (1) according to the invention. It is likewise possible to employ blue- or green-emitting complexes of the formula (1) as co-matrix for longer-wave, for example yellow-, orange- or red-emitting triplet emitters.

The cathode preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag, may also be used in addition to the said metals, in which case combinations of the metals, such as, for example, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, Li₂O, BaF₂, MgO, NaF, CsF, Cs₂CO₃, etc.). The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order either to facilitate irradiation of the organic material (O-SCs) or the coupling-out of light (OLEDs/PLEDs, O-LASERs). A preferred structure uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

All materials as are used in accordance with the prior art for the layers can generally be used in the further layers, and the person skilled in the art will be able to combine each of these materials with the materials according to the invention in an electronic device without inventive step.

The device is correspondingly structured (depending on the application), provided with contacts and finally hermetically sealed, since the lifetime of such devices is drastically shortened in the presence of water and/or air.

Preference is furthermore given to an organic electroluminescent device, characterised in that one or more layers are coated by means of a sublimation process, in which the materials are vapour-deposited in vacuum sublimation units at an initial pressure of usually less than 10⁻⁵ mbar, preferably less than 10⁻⁶ mbar. It is also possible for the initial pressure to be even lower, for example less than 10⁻⁷ mbar.

Preference is likewise given to an organic electroluminescent device, characterised in that one or more layers are coated by means of the OVPD (organic vapour phase deposition) process or with the aid of carrier-gas sublimation, in which the materials are applied at a pressure of between 10⁻⁵ mbar and 1 bar. A special case of this process is the OVJP (organic vapour jet printing) process, in which the materials are applied directly through a nozzle and thus structured (for example M. S. Arnold et al., Appl. Phys. Left. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing or offset printing, but particularly preferably LITI (light induced thermal imaging, thermal transfer printing) or ink-jet printing. Soluble compounds are necessary for this purpose, which are obtained, for example, through suitable substitution.

The organic electroluminescent device may also be produced as a hybrid system by applying one or more layers from solution and applying one or more other layers by vapour deposition. Thus, for example, it is possible to apply an emitting layer comprising a compound of the formula (1) and a matrix material from solution and to apply a hole-blocking layer and/or an electron-transport layer on top by vacuum vapour deposition.

These processes are generally known to the person skilled in the art and can be applied by him without problems to organic electroluminescent devices comprising compounds of the formula (1) or the preferred embodiments indicated above.

The electronic devices according to the invention, in particular organic electroluminescent devices, are distinguished by the following surprising advantages over the prior art:
1. Organic electroluminescent devices comprising compounds of the formula (1) as emitting materials have a very good lifetime.
2. Organic electroluminescent devices comprising compounds of the formula (1) as emitting materials have very good efficiency.
3. Organic electroluminescent devices comprising compounds of the formula (1) as emitting materials have a very low operating voltage.
4. The incorporation of the nitrogen atom as group Z makes it possible specifically to shift the emission of the compound according to the invention hypsochromically or bathochromically, in each case compared with a compound which contains a carbon atom instead of the nitrogen atom. This makes a greater range of emission colours accessible and simplifies the setting of the desired colour location.
5. The compounds according to the invention also emit at high temperatures and have no or virtually no thermal quenching. They are thus also suitable for applications which are subjected to a high thermal load.

These advantages mentioned above are not accompanied by an impairment of the other electronic properties.

The invention is explained in greater detail by the following examples, without wishing to restrict it thereby. The person skilled in the art will be able to use the descriptions to synthesise further compounds according to the invention without inventive step and use them in electronic devices and will thus be able to carry out the invention throughout the range disclosed.

### EXAMPLES

The following syntheses are carried out, unless indicated otherwise, in dried solvents under a protective-gas atmosphere. The metal complexes are additionally handled with exclusion of light or under yellow light. The solvents and reagents can be purchased, for example, from Sigma-ALDRICH or ABCR. The respective numbers in square brackets or the numbers indicated for individual compounds relate to the CAS numbers of the compounds known from the literature.

### A: Synthesis of Synthones S

### Example S1

### 5-isobutyl-2,6-naphthyridin-1-ylamine

A mixture of 18.0 g (100 mmol) of 5-chloro-2,6-naphthyridin-1-ylamine [1392428-85-1], 15.3 g (150 mmol) of isobutylboronic acid [84110-40-7], 46.1 g (200 mmol) of tripotassium phosphate monohydrate, 2.5 g (6 mmol) of S-Phos, 674 mg (3 mmol) of palladium(II) acetate, 100 g of glass beads (diameter 3 mm), 400 ml of toluene and 6 ml of water is heated under reflux for 24 h. After cooling, the reaction mixture is washed three times with 200 ml of water each time, once with 200 ml of saturated sodium chloride solution, dried over sodium sulfate, and the solvent is then removed in vacuo. Recrystallisation three times from cyclohexane. Yield 14.9 g (74 mmol), 74%. Purity about 98.0% according to ¹H-NMR.

The following compounds can be prepared analogously.

| Ex. | Boronic acid | Product | Yield |
|---|---|---|---|
| S2 | 701261-35-0 | | 67% |
| S3 | 98-80-6 | | 70% |

### B: Synthesis of the Ligands

### 1) 1,5,8a-Triazaphenanthren-6-one

### a) From 1,6-naphthyridin-5-ylamines and acetylenecarboxylic acid esters

Procedure analogous to H. Reimlinger et al., Chem. Ber., 1972, 105, 1, 108.

A mixture of 100 mmol of 1,6-naphthyridin-5-ylamine and 200 mmol of the acetylenecarboxylic acid ester in 100 ml of a dipolar protic solvent (alcohols, such as butanol, tert-butanol, cyclohexanol, ethylene glycol, glycerol, etc., or alcohol ethers, such as diethylene glycol, triethylene glycol, polyethylene glycols) is stirred at 150-200° C. for 20-60 h. The solvent is then substantially stripped off in vacuo, 50 ml of ethyl acetate and then, dropwise, 50 ml of n-heptane are added to the residue, the solid which has crystallised out is filtered off with suction and recrystallised again or purified by chromatography. The products obtained in this way are freed from low-boiling components and non-volatile secondary components by heating in a high vacuum or by fractional bulb-tube distillation or sublimation.

### Example L1

Use of 20.1 g (100 mmol) of 2-tert-butyl-1,6-naphthyridin-5-ylamine [1352329-32-8], 28.0 g (200 mmol) of methyl 4,4-dimethyl-2-pentynoate [20607-85-6] and 100 ml of cyclohexanol. Reaction time 20 h. Reaction temperature 150° C. Recrystallisation three times from ethyl acetate/n-heptane. Fractional sublimation (p about 10⁻⁵ mbar, T=210° C.). Yield 17.3 g (56 mmol), 56%. Purity about 99.5% according to ¹H-NMR.

The following compounds can be prepared analogously.

| Ex. | Amine | Alkyne | Ligand | Yield |
|---|---|---|---|---|
| L2 | 58515-45-0 | | | 61% |
| L3 | 55570-60-0 | 1388828-46-3 | | 70% |
| L4 | 899788-79-5 | | | 66% |
| L5 | 1351516-72-7 | 24342-04-9 | | 58% |
| L6 | | 80866-47-3 | | 55% |
| L7 | 1352329-33-9 | 35087-34-4 | | 51% |
| L8 | | 1236033-19-4 | | 49% |
| L9 | | 42134-60-1 | | 52% |
| L10 | | 455333-77-4 | | 55% |
| L11 | | 4891-38-7 | | 61% |
| L12 | | 7517-82-0 | | 57% |
| L13 | | 109034-21-1 | | 64% |
| L14 | | 340772-55-6 | | 53% |
| L15 | | 143952-60-7 | | 37% |
| L16 | 120266-91-3 | 20607-85-6 | | 46% |

### b) From 1,6-naphthyridin-5-ylamines and allenecarboxylic acid esters

Procedure analogous to T. Boisse et al., Tetrahedron, 2007, 63, 10511.

A mixture of 100 mmol of 1,6-naphthyridin-5-ylamine and 130 mmol of the allenecarboxylic acid ester in 100 ml of a dipolar protic solvent (alcohols, such as methanol, ethanol, butanol, tert-butanol, cyclohexanol, ethylene glycol, glycerol, etc., or alcohol ethers, such as diethylene glycol, triethylene glycol, polyethylene glycols) is stirred at the temperature indicated for 20-60 h. The solvent is then substantially stripped off in vacuo, 200 ml of dichloromethane are added to the residue, the organic phase is washed three times with 100 ml of water each time and dried over sodium sulfate. The residue obtained after removal of the solvent is purified by recrystallisation or chromatography. The products obtained in this way are freed from low-boiling components and non-volatile secondary components by heating in a high vacuum or by fractional bulb-tube distillation or sublimation.

### Example L17

Use of 20.1 g (100 mmol) of 2-tert-butyl-1,6-naphthyridin-5-ylamine [1352329-32-8], 12.8 g (130 mmol) of methyl 2,3-butadienoate [18913-35-4] and 150 ml of anhydrous isopropanol, 60° C., 20 h. Recrystallisation three times from ethyl acetate/n-heptane. Fractional sublimation (p about 10⁻⁵ mbar, T=190° C.). Yield 14.2 g (53 mmol), 53%. Purity about 99.5% according to ¹H-NMR.

The following compounds can be prepared analogously.

| | | | Ligand | |
|---|---|---|---|---|
| Ex. | Amine | Allene | ROH/T/t | Yield |
| L18 | | 18913-37-6 | MeOH/50° C./20 h | 28% |
| L19 | | 35895-72-8 | MeOH/50° C./20 h | 25% |
| L20 | | 35895-73-9 | BuOH/80° C./20 h | 31% |
| L21 | | 144542-51-8 | BuOH/80° C./20 h | 39% |
| L22 | | 74268-52-3 | EtOH/60° C./20 h | 30% |
| L23 | | 98066-39-8 | EtOH/60° C./20 h | 46% |
| L24 | 120266-91-3 | 18913-37-6 | MeOH/50° C./20 h | 19% |

### c) From 1,6-naphthyridin-5-ylamines and β-ketocarboxylic acids

A) A total of five portions of 32 mmol of dicyclohexylcarbodiimide each are added every 2 h to a vigorously stirred mixture of 100 mmol of 1,6-naphthyridin-5-ylamine, 120 mmol of the ketocarboxylic acid, 5 mmol of 4-dimethylaminopyridine and 300 ml of dichloromethane at room temperature, and the mixture is then stirred for a further 16 h. The precipitated dicyclohexylurea is filtered off, rinsed with a little dichloromethane, the reaction mixture is evaporated to about 100 ml and chromatographed on silica gel with dichloromethane, where firstly by-products are eluted and the product is then eluted by changing over to ethyl acetate. The crude product obtained in this way as an oil is reacted further in B).

B) Variant 1:

Procedure analogous to J. Heterocycl. Chem., 2004, 41, 2, 187. A mixture of 100 mmol of the carboxamide from A), 10 g of polyphosphoric acid and 45 ml of phosphoryl chloride is stirred at 100° C. for 60 h in an autoclave. After cooling, the reaction mixture is added to 500 ml of ice-water (note: exothermic!), adjusted to pH 8 using 10% by weight NaOH and extracted five times with 100 ml of dichloromethane each time. The combined dichloromethane extracts are washed once with 100 ml of water and once with 100 ml of saturated sodium chloride solution and then dried over magnesium sulfate. After evaporation, the residue is chromatographed on silica gel. The products obtained in this way are freed from low-boiling components and non-volatile secondary components by heating in a high vacuum or by fractional bulb-tube distillation or sublimation.

B) Variant 2:

50 ml (100 mmol) of a solution of lithium diisopropylamide (2.0 M in THF, ether, benzene) are added dropwise to a solution, cooled to −78° C., of 100 mmol of the carboxamide from A) in 500 ml of THF, and the mixture is stirred for 15 min. A solution of 100 mmol of 1,1,1-trifluoro-N-phenyl-N-[(trifluoromethyl)sulfonyl]methanesulfonamide [37595-74-7] in 100 ml of THF is then added dropwise, the mixture is allowed to warm to 0° C. over the course of 1 h, the reaction mixture is re-cooled to −78° C., and 50 ml (100 mmol) of a solution of lithium diisopropylamide (2.0 M in THF, ether, benzene) are added dropwise. After removal of the cooling bath and warming to room temperature, the mixture is stirred at room temperature for a further 16 h, then quenched by addition of 15 ml of methanol, the solvent is removed in vacuo, the residue is taken up in 300 ml of ethyl acetate, washed three times with 200 ml of water each time, once with 200 ml of saturated sodium chloride solution and dried over magnesium sulfate. After evaporation, the residue is chromatographed on silica gel. The products obtained in this way are freed from low-boiling components and non-volatile secondary components by heating in a high vacuum or by fractional bulb-tube distillation or sublimation.

### Example L25

A) Use of 20.1 g (100 mmol) of 2-tert-butyl-1,6-naphthyridin-5-ylamine [1352329-32-8], 25.5 g (130 mmol) of (1R,2S,4R)-4,7,7-trimethyl-3-oxobicyclo[2.2.1]heptane-2-carboxylic acid [18530-30-8], 611 mg (5 mmol) of 4-dimethylaminopyridine [1122-58-3], 33.0 g (160 mmol) of dicyclohexylcarbodiimide [538-75-0]. Chromatography on silica gel (dichloromethane/ethyl acetate 10:1, vv). Yield: 29.6 g (78 mmol), 78%. Purity about 95% according to ¹H-NMR. Mixture of the endo/exo and enol form.

Variant 1:

B) 29.6 g (78 mmol) of the carboxamide from A), 7.8 g of polyphosphoric acid, 35.1 ml of phosphoryl chloride. Chromatography on silica gel (elution with ethyl acetate, then changeover to ethyl acetate/methanol 1:1, vv). Alternatively, recrystallisation from ethanol. Fractional sublimation (p about 10⁻⁵ mbar, T=210° C.). Yield: 16.3 g (45 mmol), 58%. Purity about 99.5% according to ¹H-NMR.

The following compounds can be prepared analogously.

| | | β-Keto- | Ligand | |
|---|---|---|---|---|
| Ex. | Amine | carboxylic acid | Variant | Yield |
| L26 | | (1S,2R,4S)- 18530-29-5 | 2 | 47% |
| L27 | | (1R,2S,4S)- 59161-64-7 | 1 | 45% |
| L28 | | 63984-45-2 | 1 | 33% |
| L29 | | 60585-42-4 | 1 | 48% |
| L30 | | 59161-63-6 | 1 | 56% |
| L31 | | 102593-64-6 | 1 | 51% |
| L32 | | Prepared from 95760-70-6 by hydrolysis using PLE* | 1 | 24% |
| L33 | | Prepared from 61363-31-3 by hydrolysis using PLE* | | 20% |
| L34 | | 861359-67-3 | 1 | 23% |
| L35 | | 32530-22-6 | 1 | 21% |

*L. K. P. Lam et al., J. Org. Chem., 1986, 51, 2047.

### d) From 2-Fluoro-3-Cyanopyridines, Ketones and β-Amino Esters

100 ml of a solution of lithium diisopropylamide (2.0 M in THF, ether, benzene) are added dropwise to a solution, cooled to −78° C., of 100 mmol of the ketone, and the mixture is stirred for 15 min. A solution of 100 mmol of 2-fluoro-3-cyanopyridine in 100 ml of THF is then added dropwise. After removal of the cooling bath and warming to room temperature, the mixture is stirred at room temperature for a further 3 h. After the THF has been stripped off in vacuo, the residue is taken up in 200 ml of ethylene glycol, 110 mmol of the β-amino ester hydrochloride are added, and the mixture is heated at 180° C. on a water separator for 6 h. The mixture is subsequently allowed to cool to 60° C., stirred in air for a further 2 h, poured into 1000 ml of water, adjusted to pH=9 using ammonium hydroxide and extracted five times with 200 ml of dichloromethane each time. The combined organic phases are washed three times with 200 ml of water each time, once with 200 ml of saturated sodium chloride solution and dried over magnesium sulfate. After evaporation, the residue is chromatographed on silica gel. The products obtained in this way are freed from low-boiling components and non-volatile secondary components by heating in a high vacuum or by fractional bulb-tube distillation or sublimation.

### Example L36

Use of 12.2 g (100 mmol) of 2-fluoro-3-cyanopyridine [3939-13-7], 15.2 g (100 mmol) of (1R,4R)-1,7,7-trimethylbicyclo[2.2.1]heptan-2-one, 15.4 g (110 mmol) of β-alanine methyl ester hydrochloride [3196-73-4]. Chromatography on silica gel (dichloromethane/methanol 6:1, vv). Fractional sublimation (p about 10⁻⁵ mbar, T=200° C.). Yield: 7.0 g (23 mmol), 23%. Purity about 99% according to ¹H-NMR.

The following compounds can be prepared analogously.

| | | Ketone | | |
|---|---|---|---|---|
| | | β-Amino ester | Ligand | |
| Ex. | Pyridine | hydrochloride | Variant | Yield |
| L37 | | (1S,4R)- 2630-41-3 88512-06-5 | | 24% |
| L38 | | 58564-88-8 | | 20% |
| L39 | | 4694-11-5 | | 23% |
| L40 | | 15189-14-7 | | 25% |
| L41 | | 24669-65-5 | | 21% |

### 2) 2,5,8a-Triazaphenanthren-6-one

### a) From 2,6-naphthyridin-1-ylamines and acetylenecarboxylic acid esters

General procedure analogous to Example 1a), using 2,6-naphthyridin-1-ylamines instead of 1,6-naphthyridin-5-ylamines.

### Example L42

Use of 20.1 g (100 mmol) of 5-isobutyl-2,6-naphthyridin-1-ylamine, S1, 28.0 g (200 mmol) of methyl 4,4-dimethyl-2-pentynoate [20607-85-6] and 100 ml of cyclohexanol. Reaction time 20 h. Reaction temperature 150° C. Recrystallisation three times from ethyl acetate/n-heptane. Fractional sublimation (p about 10⁻⁵ mbar, T=200° C.). Yield 15.2 g (49 mmol), 49%. Purity about 99.5% according to ¹H-NMR.

The following compounds can be prepared analogously.

| Ex. | Amine | Alkyne | Ligand | Yield |
|---|---|---|---|---|
| L43 | S1 | | | 46% |
| L44 | S1 | | | 45% |
| L45 | S2 | | | 45% |
| L46 | S2 | | | 53% |
| L47 | S3 | | | 49% |
| L48 | S3 | | | 51% |
| L49 | S3 | | | 54% |

### a) From 2,6-naphthyridin-1-ylamines and β-ketocarboxylic acids

Preparation analogous to 1c), using 2,6-naphthyridin-1-ylamines instead of 1,6-naphthyridin-5-ylamines.

### Example L50

A) Use of 20.1 g (100 mmol) of 5-isobutyl-2,6-naphthyridin-1-ylamine S1, 25.5 g (130 mmol) of (1R,2S,4R)-4,7,7-trimethyl-3-oxobicyclo[2.2.1]-heptane-2-carboxylic acid [18530-30-8], 611 mg (5 mmol) of 4-dimethylaminopyridine, 33.0 g (160 mmol) of dicyclohexylcarbodiimide. Chromatography on silica gel (dichloromethane/ethyl acetate 10:1, vv). Yield: 30.4 g (80 mmol), 80%. Purity about 95% according to ¹H-NMR. Mixture of the endo/exo and enol form.

Variant A:

B) 30.4 g (80 mmol) of the carboxamide from A), 7.8 g of polyphosphoric acid, 35.1 ml of phosphoryl chloride. Chromatography on silica gel (elution with EA, then changeover to EA/methanol 1:1, vv). Fractional sublimation (p about 10⁻⁵ mbar, T=200° C.). Yield: 14.9 g (41 mmol), 51%. Purity about 99.5% according to 1H-NMR.

The following compounds can be prepared analogously.

| | | β-Ketocarboxylic | | |
|---|---|---|---|---|
| Ex. | Amine | acid | Ligand | Yield |
| L51 | S1 | (1R,2S,4S)- 59161-64-7 | | 47% |
| L52 | S2 | (1R,2S,4R)- 63984-45-2 | | 34% |
| L53 | S2 | 60585-42-4 | | 45% |
| L54 | S3 | 59161-63-6 | | 43% |

### C: Synthesis of the Metal Complexes

### 1) Homoleptic Tris-Facial Iridium Complexes

### Variant A: Trisacetylacetonatoiridium(III) as Iridium Starting Material

A mixture of 10 mmol of trisacetylacetonatoiridium(III) [15635-87-7], 40 mmol of the ligand L, optionally 1-10 g—typically 3 g—of an inert high-boiling additive as melting aid or solvent, for example hexadecane, m-terphenyl, triphenylene, bisphenyl ether, 3-phenoxytoluene, 1,2-, 1,3-, 1,4-bisphenoxybenzene, triphenylphosphine oxide, sulfolane, 18-crown-6, triethylene glycol, glycerol, polyethylene glycols, phenol, 1-naphthol, etc., and a glass-clad magnetic stirrer bar are melted under vacuum (10⁻⁵ mbar) into a thick-walled 50 ml glass ampoule. The ampoule is heated at the temperature indicated for the time indicated, with the molten mixture being stirred with the aid of a magnetic stirrer. In order to prevent sublimation of the ligands at relatively cold points of the ampoule, the entire ampoule must have the temperature indicated. Alternatively, the synthesis can be carried out in a stirred autoclave with glass insert. After cooling (NOTE: the ampoules are usually under pressure!), the ampoule is opened, the sinter cake is stirred for 3 h with 100 g of glass beads (diameter 3 mm) in 100 ml of a suspension medium (the suspension medium is selected so that the ligand is readily soluble therein, but the metal complex has low solubility therein; typical suspension media are methanol, ethanol, dichloromethane, acetone, THF, ethyl acetate, toluene, etc.) and mechanically digested at the same time. The fine suspension is decanted off from the glass beads, the solid is filtered off with suction, rinsed with 50 ml of the suspension medium and dried in vacuo. The dry solid is placed on an aluminium oxide bed (aluminium oxide, basic, activity grade 1) with a depth of 3-5 cm in a continuous hot extractor and then extracted with an extractant (initially introduced amount about 500 ml, the extractant is selected so that the complex is readily soluble therein at elevated temperature and has low solubility therein at low temperature; particularly suitable extractants are hydrocarbons, such as toluene, xylenes, mesitylene, naphthalene, o-dichlorobenzene, halogenated aliphatic hydrocarbons, acetone, ethyl acetate, cyclohexane). When the extraction is complete, the extractant is evaporated to about 100 ml in vacuo. Metal complexes which have excessively good solubility in the extractant are brought to crystallisation by dropwise addition of 200 ml of methanol. The solid of the suspensions obtained in this way is filtered off with suction, washed once with about 50 ml of methanol and dried. After drying, the purity of the metal complex is determined by means of NMR and/or HPLC. If the purity is below 99.5%, the hot-extraction step is repeated, with the aluminium oxide bed being omitted from the second extraction. When a purity of 99.5-99.9% or better has been achieved, the metal complex is heated or sublimed. The heating is carried out in a high vacuum (p about 10⁻⁶ mbar) in the temperature range from about 200-300° C. The sublimation is carried out in a high vacuum (p about 10⁻⁶ mbar) in the temperature range from about 300-430° C., where the sublimation is preferably carried out in the form of a fractional sublimation. If chiral ligands are employed, the derived fac-metal complexes are obtained as a diastereomer mixture. The enantiomers Λ,Δ of point group C3 generally have significantly lower solubility in the extractant than the enantiomers of point group C1, which consequently become enriched in the mother liquor. Separation of the C3 diastereomers from the C1 diastereomers in this way is frequently possible. In addition, the diastereomers can also be separated chromatographically. If ligands of point group C1 are employed in enantiomerically pure form, a diastereomer pair Λ,Δ of point group C3 is formed. The diastereomers can be separated by crystallisation or chromatography and thus obtained as enantiomerically pure compounds.

### Variant B: Tris(2,2,6,6-tetramethyl-3,5-heptanedionato)iridium(III) as iridium starting material

Procedure analogous to variant A, using 10 mmol of tris(2,2,6,6-tetramethyl-3,5-heptanedionato)iridium [99581-86-9] instead of 10 mmol of trisacetylacetonatoiridium(III) [15635-87-7]. The use of this starting material is advantageous since the build-up of pressure in the ampoule is frequently not as pronounced.

| | | | Variant | |
|---|---|---|---|---|
| | | | Additive | |
| | | | Reaction temp./ | |
| | | | reaction time | |
| | | | Suspension | |
| | | | medium | |
| Ex. | Ligand L | IR complex | Extractant | Yield |
| Ir(L1)₃ A | L1 | Ir(L1)₃ | A 1-Naphthol 280° C./30 h EtOH DCM | 62% |
| Ir(L1)₃ B | L1 | Ir(L1)₃ | B 1-Naphthol 290° C./30 h EtOH DCM | 66% |
| Ir(L2)₃ | L2 | Ir(L2)₃ | as Ir(L1)₃ A | 16% |
| Ir(L3)₃ | L3 | Ir(L3)₃ | as Ir(L1)₃ A | 20% |
| Ir(L4)₃ | L4 | Ir(L4)₃ | as Ir(L1)₃ A | 13% |
| Ir(L5)₃ | L5 | Ir(L5)₃ | as Ir(L1)₃ A | 23% |
| Ir(L6)₃ | L6 | Ir(L6)₃ | A | 60% |
| | | | 280° C./30 h | |
| | | | EtOH | |
| | | | Toluene | |
| Ir(L7)₃ | L7 | Ir(L7)₃ | as Ir(L1)₃ A | 56% |
| Ir(L8)₃ | L8 | Ir(L8)₃ | as Ir(L1)₃ A | 40% |
| Ir(L9)₃ | L9 | Ir(L9)₃ | as Ir(L1)₃ A | 39% |
| Ir(L10)₃ | L10 | Ir(L10)₃ | as Ir(L1)₃ B | 63% |
| Ir(L11)₃ | L11 | Ir(L11)₃ | as Ir(L1)₃ A | 65% |
| Ir(L12)₃ | L12 | Ir(L12)₃ | as Ir(L1)₃ A | 61% |
| Ir(L13)₃ | L13 | Ir(L13)₃ | as Ir(L1)₃ A | 58% |
| Ir(L14)₃ | L14 | Ir(L14)₃ | as Ir(L1)₃ A | 60% |
| Ir(L15)₃ | L15 | Ir(L15)₃ | as Ir(L1)₃ A | 32% |
| Ir(L16)₃ | L16 | Ir(L16)₃ | A | 18% |
| | | | 310° C./30 h | |
| | | | Acetone | |
| | | | DCM | |
| Ir(L17)₃ | L17 | Ir(L17)₃ | as Ir(L1)₃ A | 64% |
| Ir(L18)₃ | L18 | Ir(L18)₃ | as Ir(L1)₃ A | 65% |
| Ir(L19)₃ | L19 | Ir(L19)₃ | as Ir(L1)₃ A | 59% |
| Ir(L20)₃ | L20 | Ir(L20)₃ | as Ir(L1)₃ A | 60% |
| Ir(L21)₃ | L21 | Ir(L21)₃ | as Ir(L1)₃ A | 49% |
| Ir(L22)₃ | L22 | Ir(L22)₃ | as Ir(L1)₃ A | 55% |
| Ir(L23)₃ | L23 | Ir(L23)₃ | as Ir(L1)₃ A | 63% |
| Ir(L24)₃ | L24 | Ir(L24)₃ | A | 22% |
| | | | 310° C./24 h | |
| | | | Acetone | |
| | | | DCM | |
| Ir(L25)₃ | L25 | Ir(L25)₃ Diastereomer separation see below | A 1-Naphthol 280° C./45 h EtOH Toluene | 67% |
| Ir(L26)₃ | L26 | Ir(L26)₃ | as Ir(L25)₃ | 65% |
| Ir(L27)₃ | L27 | Ir(L27)₃ | as Ir(L25)₃ | 68% |
| Ir(L28)₃ | L28 | Ir(L28)₃ | as Ir(L25)₃ | 64% |
| Ir(L29)₃ | L29 | Ir(L29)₃ | as Ir(L25)₃ | 65% |
| Ir(L30)₃ | L30 | Ir(L30)₃ | as Ir(L25)₃ | 60% |
| Ir(L31)₃ | L31 | Ir(L31)₃ | as Ir(L25)₃ | 64% |
| Ir(L32)₃ | L32 | Ir(L32)₃ | as Ir(L25)₃ | 63% |
| Ir(L33)₃ | L33 | Ir(L33)₃ | as Ir(L25)₃ | 63% |
| Ir(L34)₃ | L34 | Ir(L34)₃ | as Ir(L25)₃ | 55% |
| Ir(L35)₃ | L35 | Ir(L35)₃ | as Ir(L25)₃ | 58% |
| Ir(L36)₃ | L36 | Ir(L36)₃ | as Ir(L25)₃ | 49% |
| Ir(L37)₃ | L37 | Ir(L37)₃ | as Ir(L25)₃ | 58% |
| Ir(L38)₃ | L38 | Ir(L38)₃ | as Ir(L25)₃ | 30% |
| | | Diastereomer mixture | | |
| | | C1 + Δ, Λ C3 | | |
| Ir(L39)₃ | L39 | Ir(L39)₃ | as Ir(L25)₃ | 55% |
| Ir(L40)₃ | L40 | Ir(L40)₃ | as Ir(L25)₃ | 57% |
| Ir(L41)₃ | L41 | Ir(L41)₃ | as Ir(L25)₃ | 60% |
| Ir(L42)₃ | L42 | Ir(L42)₃ | A 280° C./30 h EtOH Toluene | 56% |
| Ir(L43)₃ | L43 | Ir(L43)₃ | as Ir(L42)₃ | 49% |
| Ir(L44)₃ | L44 | Ir(L44)₃ | as Ir(L42)₃ | 58% |
| Ir(L45)₃ | L45 | Ir(L45)₃ | as Ir(L42)₃ | 45% |
| Ir(L46)₃ | L46 | Ir(L46)₃ | as Ir(L42)₃ | 60% |
| Ir(L47)₃ | L47 | Ir(L47)₃ | as Ir(L42)₃ | 40% |
| Ir(L48)₃ | L48 | Ir(L48)₃ | as Ir(L42)₃ | 53% |
| Ir(L49)₃ | L49 | Ir(L49)₃ | as Ir(L42)₃ | 56% |
| Ir(L50)₃ | L50 | | A 1-Naphthol 275° C./35 h EtOH Toluene | 54% |
| Ir(L51)₃ | L51 | Ir(L51)₃ | as Ir(L50)₃ | 56% |
| Ir(L52)₃ | L52 | Ir(L52)₃ | as Ir(L50)₃ | 52% |
| Ir(L53)₃ | L53 | Ir(L53)₃ | as Ir(L50)₃ | 50% |
| Ir(L54)₃ | L54 | Ir(L54)₃ | as Ir(L50)₃ | 53% |

Separation of the diastereomers of Ir(L25)₃:

Chromatography on silica gel with ethyl acetate:

Diastereomer 1: R_{f} about 0.7

Diastereomer 2: R_{f} about 0.2

After elution of diastereomer 1, changeover to DMF in order to elute diastereomer 2.

### 2) Heteroleptic Iridium Complexes:

### Variant A:

### Step 1:

A mixture of 10 mmol of sodium bisacetylacetonatodichloroiridate(III) [770720-50-8] and 22 mmol of the ligand L, optionally 1-10 g of an inert high-boiling additive as melting aid or solvent, as described under 1), and a glass-clad magnetic stirrer bar are melted under vacuum (10⁻⁵ mbar) into a thick-walled 50 ml glass ampoule. The ampoule is heated at the temperature indicated for the time indicated, with the molten mixture being stirred with the aid of a magnetic stirrer. After cooling—NOTE: the ampoules are usually under pressure!—the ampoule is opened, the sinter cake is stirred for 3 h with 100 g of glass beads (diameter 3 mm) in 100 ml of the suspension medium indicated (the suspension medium is selected so that the ligand is readily soluble therein, but the chloro dimer of the formula [Ir(L)₂Cl]₂ has low solubility therein; typical suspension media are MeOH, EtOH, DCM, acetone, ethyl acetate, toluene, etc.) and mechanically digested at the same time. The fine suspension is decanted off from the glass beads, the solid ([Ir(L)₂Cl]₂ which also contains about 2 eq. of NaCl, called the crude chloro dimer below) is filtered off with suction and dried in vacuo.

### Step 2:

The crude chloro dimer of the formula [Ir(L)₂Cl]₂ obtained in this way is suspended in a mixture of 75 ml of 2-ethoxyethanol and 25 ml of water, 15 mmol of the co-ligand CL or the co-ligand compound CL and 15 mmol of sodium carbonate are added. After 20 h under reflux, a further 75 ml of water are added dropwise, the mixture is cooled, the solid is filtered off with suction, washed three times with 50 ml of water each time and three times with 50 ml of methanol each time and dried in vacuo. The dry solid is placed on an aluminium oxide bed (aluminium oxide, basic, activity grade 1) with a depth of 3-5 cm in a continuous hot extractor and then extracted with the extractant indicated (initially introduced amount about 500 ml, the extractant is selected so that the complex is readily soluble therein at elevated temperature and has low solubility therein at low temperature; particularly suitable extractants are hydrocarbons, such as toluene, xylenes, mesitylene, naphthalene, o-dichlorobenzene, acetone, ethyl acetate, cyclohexane). When the extraction is complete, the extractant is evaporated to about 100 ml in vacuo. Metal complexes which have excessively good solubility in the extractant are brought to crystallisation by dropwise addition of 200 ml of methanol. The solid of the suspensions obtained in this way is filtered off with suction, washed once with about 50 ml of methanol and dried. After drying, the purity of the metal complex is determined by means of NMR and/or HPLC. If the purity is below 99.5%, the hot-extraction step is repeated; when a purity of 99.5-99.9% or better has been achieved, the metal complex is heated or sublimed. Besides the hot-extraction method of purification, the purification can also be carried out by chromatography on silica gel or aluminium oxide. The heating is carried out in a high vacuum (p about 10⁻⁶ mbar) in the temperature range from about 200-300° C. The sublimation is carried out in a high vacuum (p about 10⁻⁶ mbar) in the temperature range from about 300-400° C., where the sublimation is preferably carried out in the form of a fractional sublimation.

| | | | Ir complex | |
|---|---|---|---|---|
| | | | Step 1: | |
| | | | Additive | |
| | | | Reaction temp./reaction | |
| | Li- | Co- | time/suspension medium | |
| | gand | ligand | Step 2: | |
| Ex. | L | CL | Extractant | Yield |
| Ir(L1)₂(CL1) | L1 | 123-54-6 CL1 | 280° C./20 h/EtOH Ethyl acetate | 53% |
| Ir(L25)₂(CL1) | L25 | CL1 | Hexadecane 280° C./20 h/EtOH Ethyl acetate | 57% |
| Ir(L39)₂(CL1) | L39 | CL1 | 280° C./20 h/EtOH Ethyl acetate | 57% |
| Ir(L42)₂(CL1) | L42 | CL1 | 280° C./20 h/EtOH Ethyl acetate | 55% |
| Ir(L46)₂(CL1) | L46 | CL1 | 280° C./24 h/EtOH Ethyl acetate | 47% |
| Ir(L48)₂(CL1) | L48 | 1118-71-4 CL2 | 280° C./20 h/EtOH Cyclohexane | 49% |
| Ir(L50)₂(CL1) | L50 | CL2 | 280° C./25 h/EtOH Cyclohexane | 54% |
| Ir(L53)₂(CL2) | L53 | CL2 | 280° C./20 h/EtOH Cyclohexane | 60% |
| Ir(L1)₂(CL3) | L1 | 98-98-6 CL3 | 280° C./20 h/EtOH Cyclohexane | 54% |
| Ir(L13)₂(CL4) | L13 | 18653-75-3 CL4 | 280° C./20 h/EtOH Cyclohexane | 49% |
| Ir(L25)₂(CL5) | L25 | 14782-58-2 CL5 | Hexadecane 280° C./20 h/EtOH Ethyl acetate | 56% |
| Ir(L29)₂(CL6) | L29 | 219508-27-7 CL6 | Hexadecane 280° C./20 h/EtOH Toluene | 57% |
| Ir(L39)₂(CL6) | L39 | 219508-27-7 CL6 | 280° C./20 h/EtOH Toluene | 57% |

### Variant B:

### Step 1:

See variant A, step 1.

### Step 2:

The crude chloro dimer of the formula [Ir(L)₂Cl]₂ obtained in this way is suspended in 200 ml of THF, 10 mmol of the co-ligand CL, 10 mmol of silver(I) trifluoroacetate and 20 mmol of potassium carbonate are added to the suspension, and the mixture is heated under reflux for 24 h. After cooling, the THF is removed in vacuo. The residue is taken up in 200 ml of a mixture of ethanol and conc. ammonia solution (1:1, vv). The suspension is stirred at room temperature for 1 h, the solid is filtered off with suction, washed twice with 50 ml of a mixture of ethanol and conc. ammonia solution (1:1, vv) each time and twice with 50 ml of ethanol each time and then dried in vacuo. Hot extraction or chromatography and sublimation as in variant A.

| | | | Ir complex | |
|---|---|---|---|---|
| | | | Step 1: | |
| | | | Additive | |
| | | | Reaction temp./reaction | |
| | Li- | Co- | time/suspension medium | |
| | gand | ligand | Step 2: | |
| Ex. | L | CL | Extractant | Yield |
| Ir(L1)₂(CL7) | L1 | 391604-55-0 CL7 | 280° C./24 h/EtOH Toluene | 56% |
| Ir(L25)₂(CL8) | L25 | 4350-51-0 CL8 | Hexadecane 280° C./24 h/EtOH Toluene | 51% |
| Ir(L29)₂(CL9) | L29 | 1093072-00- 4 CL9 | Hexadecane 280° C./24 h/EtOH Cyclohexane | 49% |
| Ir(L39)₂(CL10) | L39 | 152536- 39-5 CL10 | 280° C./24 h/EtOH Toluene | 52% |

### Variant C:

### Step 1:

See variant A, step 1.

### Step 2:

The crude chloro dimer of the formula [Ir(L)₂Cl]₂ obtained in this way is suspended in 500 ml of dichloromethane and 100 ml of ethanol, 10 mmol of silver(I) trifluoromethanesulfonate are added to the suspension, and the mixture is stirred at room temperature for 24 h. The precipitated solid (AgCl) is filtered off with suction via a short Celite bed, and the filtrate is evaporated to dryness in vacuo. The solid obtained in this way is taken up in 100 ml of ethylene glycol, 10 mmol of the co-ligand CL and 10 mmol of 2,6-dimethylpyridine are added, and the mixture is then stirred at 130° C. for 30 h. After cooling, the solid is filtered off with suction, washed twice with 50 ml of ethanol each time and dried in vacuo. Hot extraction or chromatography and sublimation as in variant A.

| | | | Ir complex | |
|---|---|---|---|---|
| | | | Step 1: | |
| | | | Additive | |
| | | | Reaction temp./reaction | |
| | Li- | Co- | time/suspension medium | |
| | gand | ligand | Step 2: | |
| Ex. | L | CL | Extractant | Yield |
| Ir(L6)₂(CL11) | L6 | 914306- 48-2 CL11 | 280° C./24 h/EtOH Toluene Purification by chromatography on silica gel Eluent Tol:EA 9:1, vv | 49% |
| Ir(L20)₂(CL11) | L20 | CL11 | 280° C./24 h/EtOH Toluene | 46% |
| Ir(L30)₂(CL12) | L30 | 39696-58-7 CL12 | Hexadecane 280° C./24 h/EtOH Toluene | 54% |
| Ir(L48)₂(CL13) | L48 | 26274-35-1 CL13 | 280° C./24 h/EtOH Toluene Purification by chromatography on silica gel Eluent DCM | 49% |
| Ir(L50)₂(CL14) | L50 | 3297-72-1 CL14 | Hexadecane 280° C./24 h/EtOH Toluene | 44% |

### Variant E:

A mixture of 10 mmol of the Ir complex Ir(L)₂(CL1 or CL2), 11 mmol of the ligand L′, optionally 1-10 g of an inert high-boiling additive as melting aid or solvent, as described under 1), and a glass-clad magnetic stirrer bar are melted under vacuum into a 50 ml glass ampoule (10⁻⁵ mbar). The ampoule is heated at the temperature indicated for the time indicated, with the molten mixture being stirred with the aid of a magnetic stirrer. Further work-up, purification and sublimation as described under 1) for homoleptic tris-facial iridium complexes.

| | | | Ir complex | |
|---|---|---|---|---|
| | | | Additive | |
| | | Li- | Reaction temp./reaction | |
| | Ir complex | gand | time/suspension medium | |
| Ex. | Ir(L)₂(CL) | L′ | Extractant | Yield |
| Ir(L1)₂(L25) | Ir(L1)₂(CL1) | L25 | Hexadecane 280° C./45 h/EtOH Toluene | 59% |
| Ir(L25)₂(L1) | Ir(L25)₂(CL1) | L1 | as Ir(L1)₂(L25) | 47% |
| Ir(L25)₂(L39) | Ir(L25)₂(CL1) | L39 | as Ir(L1)₂(L25) | 53% |

### Example S4

### 8-tert-Butyl-1,6-naphthyridine 6-N-oxide

### a) 8-tert-Butyl-1,6-naphthyridine

Procedure analogous to A. Joshi-Pangu et al., J. Am. Chem. Soc., 2011, 133, 22, 8478. 100 ml of tert-butylmagnesium chloride, 2 M solution in THF, are added dropwise to a solution, cooled to −10° C., of 20.9 g (100 mmol) of 8-bromo-1,6-naphthyridine [17965-74-1], 1.5 g (10 mmol) of nickel(II) chloride×1.5 H₂O and 3.2 g (10 mmol) of 1,3-dicyclohexyl-1H-imidazolium tetrafluoroborate [286014-37-7] in 300 ml of THF, and the mixture is then stirred for a further 8 h. After warming to 0° C., 20 ml of water are added dropwise, 300 ml of saturated ammonium chloride solution and 500 ml of ethyl acetate are then added. After vigorous shaking, the organic phase is separated off, washed once with 500 ml of water and once with 300 ml of saturated sodium chloride solution and then dried over magnesium sulfate. After removal of the solvent, the residue is chromatographed on silica gel with ethyl acetate:heptane:triethylamine (1:2:0.05). Yield: 3.4 g (18 mmol), 18%. Purity about 98% according to ¹H-NMR.

### b) 8-tert-Butyl-1,6-naphthyridine 6-N-oxide, S4

5.1 g (30 mmol) of m-chloroperbenzoic acid are added in portions to a solution of 3.4 g (18 mmol) of 8-tert-butyl-1,6-naphthyridine in 50 ml of chloroform, and the mixture is then stirred at room temperature for 4 days. After addition of 200 ml of chloroform, the reaction solution is washed three times with 100 ml of a 10% potassium carbonate solution each time and dried over magnesium sulfate. The solid obtained after removal of the solvent is reacted further without further purification. Yield: 3.6 g (18 mmol) quantitative, purity: 95% according to ¹H-NMR.

### 1e) From 5-halo-1,6-naphthyridines and β-ketocarboxylic acid amides

A) A mixture of 100 mmol of 5-halo-1,6-naphthyridine (halogen=chlorine, bromine, iodine), 120 mmol of the β-ketocarboxylic acid amide, 300 mol of a base (sodium carbonate, potassium carbonate, caesium carbonate, potassium phosphate, etc.), 5 mmol of a bidentate phosphine (BINAP, xantphos) or 10 mmol of a monodentate phosphine (S-Phos, X-Phos, BrettPhos), 5 mmol of palladium(II) acetate and 100 g of glass beads (diameter 6 mm) in 500 ml of a solvent (dioxane, DMF, DMAC, etc.) is stirred vigorously at 80-150° C. for 16 h. After cooling, the solvent is removed in vacuo, the residue is taken up in 1000 ml of ethyl acetate, washed three times with 300 ml of water each time, once with 300 ml of saturated sodium chloride solution and then dried over magnesium sulfate.

B) The residue obtained after removal of the solvent in vacuo is cyclised as described in 1c) step B) variant 1.

### Example L18

A+B) Use of 22.1 g (100 mmol) of 5-chloro-2-(tert-butyl)-1,6-naphthyridine [1352329-30-6], 13.8 g (120 mmol) of 2-acetylpropionamide [4433-76-5], 41.5 g (300 mmol) of potassium carbonate, 2.9 g (5 mmol) of xantphos, 1.1 g (5 mmol) of palladium(II) acetate, 500 ml of dioxane, T=110° C. Purification by column chromatography (silica gel, DCM:EA 5:1, vv) and recrystallisation three times from ethyl acetate/n-heptane. Fractional sublimation (p about 10⁻⁵ mbar, T=200° C.). Yield 4.7 g (17 mmol), 17%. Purity about 99.5% according to ¹H-NMR.

The following compounds can be prepared analogously.

| | 5-Halo-1,6- | | | |
|---|---|---|---|---|
| Ex. | naphthyridine | Amide | Ligand | Yield |
| L60 | | 99063-20-4 | | 12% |
| L61 | 1086385-19-4 | | | 10% |
| L62 | 1339335-80-6 | | | 9% |

### 1f) From 1,6-naphthyridine 6-N-oxides and β-ketocarboxylic acid amides

A) Procedure analogous to M. Couturier et al., Org. Lett. 2006, 9, 1929. 100 mmol of oxalyl chloride are added dropwise at room temperature to a suspension of 100 mmol of the amide in 100 ml of 1,2-dichloroethane, and the mixture is then stirred at 50° C. for 3 h. After cooling to room temperature, 50 mmol of the 1,6-naphthyridine 6-N-oxide dissolved in 100 ml of 1,2-dichloroethane are added, and the mixture is stirred at room temperature for a further 24 h.

B) The residue obtained after removal of the solvent in vacuo is cyclised as described in 1c) step B) variant 1.

### Example L63

A+B) Use of 11.5 g (100 mmol) of 2-acetylpropionamide [4433-76-5], 8.6 ml (100 mmol) of oxalyl chloride [79-37.8] and 8.0 g (50 mmol) 8-methyl-1,6-naphthyridine 6-N-oxide [107771-62-0]. Purification by column chromatography (silica gel, DCM:EA 5:1, vv) and recrystallisation three times from ethyl acetate/n-heptane. Fractional sublimation (p about 10⁻⁵ mbar, T=190° C.). Yield: 2.7 g (11 mmol), 22%. Purity about 99.5% according to ¹H-NMR.

The following compounds can be prepared analogously.

| | 1,6-Naphthyridine | | | |
|---|---|---|---|---|
| Ex. | 6-N-oxide | Amide | Ligand | Yield |
| L64 | | | | 13% |
| L65 | S4 | | | 14% |
| L66 | | 69604-10-0 | | 10% |
| L67 | | 872823-41-1 | | 16% |

### 1 g) From 7-(1,6-naphthyridin-5-yl)-1,5,7,8a-tetraazaphenanthrene-6,8-diones and enamines

A) A mixture of 100 mmol of 7-(1,6-naphthyridin-5-yl)-1,5,7,8a-tetraazaphenanthrene-6,8-dione (dimeric isocyanate, synthesis analogous to 4737-19-3 in accordance with K. J. Duffy et al., WO2007150011) and 500 mmol of the enamine is stirred at 160° C. on a water separator for 16 h. The temperature is then slowly increased to about 280° C. until the secondary amine formed and the excess enamine have distilled off. After cooling, the residue is chromatographed.

### Example L65

A) Use of 45.5 g (100 mmol) of 10-tert-butyl-7-(8-tert-butyl-1,6-naphthyridin-5-yl)-1,5,7,8a-tetraazaphenanthrene-6,8-dione, 105.7 g (500 mmol) of 4-(2,2,5,5-tetramethyl-2,5-dihydrofuran-3-yl)morpholine (preparation analogous to 78593-93-8 in accordance with R. Carlson et al., Acta Chem. Scand. B, 1984, B38, 1, 49).

Purification by column chromatography (silica gel, DCM:EA 5:1, vv) and recrystallisation three times from ethyl acetate/n-heptane. Fractional sublimation (p about 10⁻⁵ mbar, T=200° C.). Yield 4.9 g (14 mmol), 14%. Purity about 99.5% according to ¹H-NMR.

The following compounds can be prepared analogously.

| | Dimeric | | | |
|---|---|---|---|---|
| Ex. | isocyanate | Enamine | Ligand | Yield |
| L67 | | 78593-93-8 | | 29% |
| L68 | | 41455-20-3 | | 36% |
| L69 | | 84395-66-4 | | 20% |
| L70 | | 36838-59-2 | | 38% |

### 1h) From 2-halopyridinecarboxylic acid amides, β-ketocarboxylic acid amides and alkynes

A) An intimate mixture of 120 mmol of the 2-halopyridinecarboxylic acid amide and 100 mmol of the β-ketocarboxylic acid amide is melted on a water separator and then stirred at 240° C. until (about 2 h) water no longer separates off. After cooling, the melt cake is washed by stirring with 200 ml of hot methanol/water (1:1, vv). The solid obtained after filtration and drying is reacted further in B).

B) 6 mmol of triphenylphosphine, 3 mmol of palladium(II) acetate, 3 mmol of copper(I) iodide and 150 mmol of the alkyne are added consecutively to a solution of 100 mmol of the 2-pyridin-3-yl-1H-pyrimidin-4-one from A) in 200 ml of DMF and 100 ml of triethylamine, and the mixture is stirred at 70° C. for 5 h. After cooling, the precipitated triethylammonium hydrochloride is filtered off with suction, rinsed with a little DMF, and the filtrate is freed from the volatile components in vacuo. The residue is dissolved in 200 ml of nitrobenzene, 10 ml of water are added, the mixture is slowly heated to 200° C. and then stirred at 200° C. on a water separator for 6 h. The nitrobenzene is then distilled off completely at 200° C. by application of a slight reduced pressure. After cooling, the glassy residue is taken up in 150 ml of hot methanol, during which the product begins to crystallise. After cooling, the solid is filtered off with suction, rinsed with a little methanol and recrystallised again.

### Example L71

A+B) Use of 29.2 g (120 mmol) of 2-bromo-6-propyl-3-pyridinecarboxamide [1237981-90-6], 18.5 g (100 mmol) of tetrahydro-2,2,5,5-tetramethyl-4-oxo-3-furancarboxamide [99063-20-4], 1.6 g (6 mmol) of triphenylphosphine, 673 mg (3 mmol) of palladium(II) acetate, 571 mg (3 mmol) of copper(I) iodide and 14.7 g (150 mmol) of trimethylsilylacetylene [1066-54-2]. Recrystallisation three times from methanol. Fractional sublimation (p about 10 mbar, T=200° C.). Yield: 9.1 g (27 mmol), 27%. Purity about 99.5% according to ¹H-NMR.

The following compounds can be prepared analogously.

| | Pyridine-carbox- | Amide | | |
|---|---|---|---|---|
| Ex. | amide | Alkyne | Ligand | Yield |
| L72 | 54957-84-5 | | | 30% |
| L73 | 386704-05-8 | | | 28% |
| L74 | 4138-21-0 | 917-92-0 | | 27% |

### C: Synthesis of the Metal Complexes

### 1) Homoleptic Tris-Facial Iridium Complexes:

| | | | Variant | |
|---|---|---|---|---|
| | | | Addition | |
| | | | Reaction temp./ | |
| | | | reaction time | |
| | Ligand | | Suspension medium | |
| Ex. | L | Ir complex | Extractant | Yield |
| Ir(L60)₃ | L60 | Ir(L60)₃ | A Hydroquinone 260° C./30 h EtOH DCM | 56% |
| Ir(L61)₃ | L61 | Ir(L61)₃ | as Ir(L60)₃ | 32% |
| Ir(L62)₃ | L62 | Ir(L62)₃ | as Ir(L60)₃ | 17% |
| Ir(L63)₃ | L63 | Ir(L63)₃ | as Ir(L60)₃ | 51% |
| Ir(L64)₃ | L64 | Ir(L64)₃ | as Ir(L60)₃ | 48% |
| Ir(L65)₃ | L65 | Ir(L65)₃ | as Ir(L60)₃ | 45% |
| Ir(L66)₃ | L66 | Ir(L66)₃ | as Ir(L60)₃ | 30% |
| Ir(L67)₃ | L67 | Ir(L67)₃ | as Ir(L60)₃ | 49% |
| Ir(L68)₃ | L68 | Ir(L68)₃ | as Ir(L60)₃ | 44% |
| Ir(L69)₃ | L69 | Ir(L69)₃ | as Ir(L60)₃ | 46% |
| Ir(L70)₃ | L70 | Ir(L70)₃ | as Ir(L60)₃ | 51% |
| Ir(L71)₃ | L71 | Ir(L71)₃ | as Ir(L60)₃ | 21% |
| Ir(L72)₃ | L72 | Ir(L72)₃ | as Ir(L60)₃ | 25% |
| Ir(L73)₃ | L73 | Ir(L73)₃ | as Ir(L60)₃ | 30% |
| Ir(L74)₃ | L74 | Ir(L74)₃ | as Ir(L60)₃ | 48% |

### Production of OLEDs

### 1) Vacuum-Processed Devices:

OLEDs according to the invention and OLEDs in accordance with the prior art are produced by a general process in accordance with WO 2004/058911, which is adapted to the circumstances described here (layer-thickness variation, materials used).

The results for various OLEDs are presented in the following examples. Glass plates with structured ITO (indium tin oxide) form the substrates to which the OLEDs are applied. The OLEDs have in principle the following layer structure: substrate/hole-transport layer 1 (HTL1) consisting of HTM doped with 3% of NDP-9 (commercially available from Novaled), 20 nm/hole-transport layer 2 (HTL2)/optional electron-blocking layer (EBL)/emission layer (EML)/optional hole-blocking layer (HBL)/electron-transport layer (ETL)/optional electron-injection layer (EIL) and finally a cathode. The cathode is formed by an aluminium layer with a thickness of 100 nm.

Firstly, vacuum-processed OLEDs are described. For this purpose, all materials are applied by thermal vapour deposition in a vacuum chamber. The emission layer here always consists of at least one matrix material (host material) and an emitting dopant (emitter), which is admixed with the matrix material or matrix materials in a certain proportion by volume by coevaporation. An expression such as M3:M2:Ir(L1)₃ (55%:35%:10%) here means that material M3 is present in the layer in a proportion by volume of 55%, M2 is present in the layer in a proportion of 35% and Ir(L1)₃ is present in the layer in a proportion of 10%. Analogously, the electron-transport layer may also consist of a mixture of two materials. The precise structure of the OLEDs is shown in Table 1. The materials used for the production of the OLEDs are shown in Table 6.

The OLEDs are characterised by standard methods. For this purpose, the electroluminescence spectra, the current efficiency (measured in cd/A) and the voltage (measured at 1000 cd/m² in V) are determined from current/voltage/luminance characteristic lines (IUL characteristic lines). For selected experiments, the lifetime is determined. The lifetime is defined as the time after which the luminous density has dropped to a certain proportion from a certain initial luminous density. The expression LT50 means that the lifetime given is the time at which the luminous density has dropped to 50% of the initial luminous density, i.e. from, for example, 1000 cd/m² to 500 cd/m². Depending on the emission colour, different initial luminances were selected. The values for the lifetime can be converted to a figure for other initial luminous densities with the aid of conversion formulae known to the person skilled in the art. The lifetime for an initial luminous density of 1000 cd/m² is a usual figure here.

### Use of Compounds According to the Invention as Emitter Materials in Phosphorescent OLEDs

The compounds according to the invention can be employed, inter alia, as phosphorescent emitter materials in the emission layer in OLEDs. Compound Ir(Ref1)₃ is used as comparison in accordance with the prior art. The results for the OLEDs are summarised in Table 2.

TABLE 1
Structure of the OLEDs

| | | | | | |
|---|---|---|---|---|---|
| | HTL2 | EBL | EML | HBL | ETL |
| Ex. | Thickness | Thickness | Thickness | Thickness | Thickness |

Green OLED

| | | | | | |
|---|---|---|---|---|---|
| D-Ir(Ref1)₃ | HTM | — | M3:M2:Ir(Ref1)₃ | HBM | ETM1:ETM2 |
| | 220 nm | | (65%:30%:5%) | 10 nm | (50%:50%) |
| | | | 25 nm | | 20 nm |

Blue OLEDs

| | | | | | |
|---|---|---|---|---|---|
| D-Ir(L1)₃ | HTM | EBM | M1:M4:Ir(L1)₃ | HBM | ETM1:ETM2 |
| | 180 nm | 20 nm | (65%:30%:5%) | 10 nm | (50%:50%) |
| | | | 25 nm | | 30 nm |
| D-Ir(L6)₃ | HTM | EBM | M1:Ir(L6)₃ | HBM | ETM1:ETM2 |
| | 180 nm | 20 nm | (90%:10%) | 10 nm | (50%:50%) |
| | | | 25 nm | | 30 nm |
| D-Ir(L13)₃ | HTM | EBM | M1:M8:Ir(L13)₃ | HBM | ETM1:ETM2 |
| | 180 nm | 20 nm | (50%:45%:5%) | 10 nm | (50%:50%) |
| | | | 25 nm | | 30 nm |
| D-Ir(L16)₃ | HTM | EBM | M1:M9:Ir(L16)₃ | HBM | ETM1:ETM2 |
| | 180 nm | 20 nm | (50%:45%:5%) | 10 nm | (50%:50%) |
| | | | 25 nm | | 30 nm |
| D-Ir(L18)₃ | HTM | EBM | M1:M4:Ir(L18)₃ | HBM | ETM1:ETM2 |
| | 180 nm | 20 nm | (65%:30%:5%) | 10 nm | (50%:50%) |
| | | | 25 nm | | 30 nm |
| D-Ir(L24)₃ | HTM | EBM | M1:M8:Ir(L24)₃ | HBM | ETM1:ETM2 |
| | 180 nm | 20 nm | (50%:45%:5%) | 10 nm | (50%:50%) |
| | | | 25 nm | | 30 nm |
| D-Ir(L25)₃ | HTM | EBM | M1:M4:Ir(L25)₃ | HBM | ETM1:ETM2 |
| | 180 nm | 20 nm | (65%:30%:5%) | 10 nm | (50%:50%) |
| | | | 25 nm | | 30 nm |
| D-Ir(L29)₃ | HTM | EBM | M7:M9:Ir(L29)₃ | HBM | ETM1:ETM2 |
| | 180 nm | 20 nm | (60%:30%:10%) | 10 nm | (50%:50%) |
| | | | 25 nm | | 30 nm |
| D-Ir(L30)₃ | HTM | EBM | M7:M9:Ir(L30)₃ | HBM | ETM1:ETM2 |
| | 180 nm | 20 nm | (60%:30%:10%) | 10 nm | (50%:50%) |
| | | | 25 nm | | 30 nm |
| D-Ir(L37)₃ | HTM | EBM | M1:M9:Ir(L37)₃ | HBM | ETM1:ETM2 |
| | 180 nm | 20 nm | (70%:20%:10%) | 10 nm | (50%:50%) |
| | | | 25 nm | | 30 nm |
| D-Ir(L37)₃ | HTM | EBM | M1:M9:Ir(L37)₃ | HBM | ETM1:ETM2 |
| | 180 nm | 20 nm | (70%:20%:10%) | 10 nm | (50%:50%) |
| | | | 25 nm | | 30 nm |
| D-Ir(L39)₃ | HTM | EBM | M1:M4:Ir(L39)₃ | HBM | ETM1:ETM2 |
| | 180 nm | 20 nm | (65%:30%:5%) | 10 nm | (50%:50%) |
| | | | 25 nm | | 30 nm |
| D-Ir(L40)₃ | HTM | EBM | M1:M9:Ir(L40)₃ | HBM | ETM1:ETM2 |
| | 180 nm | 20 nm | (70%:20%:10%) | 10 nm | (50%:50%) |
| | | | 25 nm | | 30 nm |
| D-Ir(L41)₃ | HTM | EBM | M1:M9:Ir(L41)₃ | HBM | ETM1:ETM2 |
| | 180 nm | 20 nm | (75%:20%:5%) | 10 nm | (50%:50%) |
| | | | 25 nm | | 30 nm |
| D-Ir(L60)₃ | HTM | EBM | M1:M9:Ir(L60)₃ | HBM | ETM1:ETM2 |
| | 180 nm | 20 nm | (70%:20%:10%) | 10 nm | (50%:50%) |
| | | | 25 nm | | 30 nm |
| D-Ir(L63)₃ | HTM | EBM | M1:M3:Ir(L63)₃ | HBM | ETM1:ETM2 |
| | 180 nm | 20 nm | (80%:10%:10%) | 10 nm | (50%:50%) |
| | | | 25 nm | | 30 nm |
| D-Ir(L64)₃ | HTM | EBM | M1:M3:Ir(L64)₃ | HBM | ETM1:ETM2 |
| | 180 nm | 20 nm | (80%:10%:10%) | 10 nm | (50%:50%) |
| | | | 25 nm | | 30 nm |
| D-Ir(L65)₃ | HTM | EBM | M1:M3:Ir(L65)₃ | HBM | ETM1:ETM2 |
| | 180 nm | 20 nm | (80%:10%:10%) | 10 nm | (50%:50%) |
| | | | 25 nm | | 30 nm |
| D-Ir(L66)₃ | HTM | EBM | M1:M3:Ir(L66)₃ | HBM | ETM1:ETM2 |
| | 180 nm | 20 nm | (80%:10%:10%) | 10 nm | (50%:50%) |
| | | | 25 nm | | 30 nm |
| D-Ir(L67)₃ | HTM | EBM | M1:M3:Ir(L67)₃ | HBM | ETM1:ETM2 |
| | 180 nm | 20 nm | (80%:10%:10%) | 10 nm | (50%:50%) |
| | | | 25 nm | | 30 nm |
| D-Ir(L68)₃ | HTM | EBM | M1:M3:Ir(L68)₃ | HBM | ETM1:ETM2 |
| | 180 nm | 20 nm | (80%:10%:10%) | 10 nm | (50%:50%) |
| | | | 25 nm | | 30 nm |
| D-Ir(L69)₃ | HTM | EBM | M1:M3:Ir(L69)₃ | HBM | ETM1:ETM2 |
| | 180 nm | 20 nm | (80%:10%:10%) | 10 nm | (50%:50%) |
| | | | 25 nm | | 30 nm |
| D-Ir(L70)₃ | HTM | EBM | M1:M3:Ir(L70)₃ | HBM | ETM1:ETM2 |
| | 180 nm | 20 nm | (80%:10%:10%) | 10 nm | (50%:50%) |
| | | | 25 nm | | 30 nm |
| D-Ir(L71)₃ | HTM | EBM | M1:M3:Ir(L71)₃ | HBM | ETM1:ETM2 |
| | 180 nm | 20 nm | (80%:10%:10%) | 10 nm | (50%:50%) |
| | | | 25 nm | | 30 nm |
| D-Ir(L72)₃ | HTM | EBM | M1:M3:Ir(L72)₃ | HBM | ETM1:ETM2 |
| | 180 nm | 20 nm | (80%:10%:10%) | 10 nm | (50%:50%) |
| | | | 25 nm | | 30 nm |
| D-Ir(L73)₃ | HTM | EBM | M1:M3:Ir(L73)₃ | HBM | ETM1:ETM2 |
| | 180 nm | 20 nm | (70%:20%:10%) | 10 nm | (50%:50%) |
| | | | 25 nm | | 30 nm |
| D-Ir(L74)₃ | HTM | EBM | M1:M3:Ir(L74)₃ | HBM | ETM1:ETM2 |
| | 180 nm | 20 nm | (80%:10%:10%) | 10 nm | (50%:50%) |
| | | | 25 nm | | 30 nm |
| D-Ir(L39)₂(CL1) | HTM | EBM | M1:M9:Ir(L39)₂(CL1) | HBM | ETM1:ETM2 |
| | 180 nm | 20 nm | (80%:10%:10%) | 10 nm | (50%:50%) |
| | | | 25 nm | | 30 nm |
| D-Ir(L1)₂(CL3) | HTM | EBM | M1:M9:Ir(L1)₂(CL3) | HBM | ETM1:ETM2 |
| | 180 nm | 20 nm | (80%:10%:10%) | 10 nm | (50%:50%) |
| | | | 25 nm | | 30 nm |
| D-Ir(L29)₂(CL6) | HTM | EBM | M1:Ir(L29)₂(CL6) | HBM | ETM1:ETM2 |
| | 180 nm | 20 nm | (90%:10%) | 10 nm | (50%:50%) |
| | | | 25 nm | | 30 nm |
| D-Ir(L39)₂(CL6) | HTM | EBM | M1:M3:Ir(L39)₂(CL6) | HBM | ETM1:ETM2 |
| | 180 nm | 20 nm | (80%:10%:10%) | 10 nm | (50%:50%) |
| | | | 25 nm | | 30 nm |
| D-Ir(L1)₂(CL7) | HTM | EBM | M1:M3:Ir(L1)₂(CL7) | HBM | ETM1:ETM2 |
| | 180 nm | 20 nm | (80%:10%:10%) | 10 nm | (50%:50%) |
| | | | 25 nm | | 30 nm |
| D-Ir(L25)₂(CL8) | HTM | EBM | M1:M3:Ir(L25)₂(CL8) | HBM | ETM1:ETM2 |
| | 180 nm | 20 nm | (80%:10%:10%) | 10 nm | (50%:50%) |
| | | | 25 nm | | 30 nm |
| D-Ir(L29)₂(CL9) | HTM | EBM | M1:M4:Ir(L29)₂(CL9) | HBM | ETM1:ETM2 |
| | 180 nm | 20 nm | (65%:30%:5%) | 10 nm | (50%:50%) |
| | | | 25 nm | | 30 nm |
| D-Ir(L39)₂(CL10) | HTM | EBM | M1:Ir(L39)₂(CL10) | HBM | ETM1:ETM2 |
| | 180 nm | 20 nm | (90%:10%) | 10 nm | (50%:50%) |
| | | | 25 nm | | 30 nm |
| D-Ir(L6)₂(CL11) | HTM | EBM | M1:M9:Ir(L6)₂(CL11) | HBM | ETM1:ETM2 |
| | 180 nm | 20 nm | (80%:10%:10%) | 10 nm | (50%:50%) |
| | | | 25 nm | | 30 nm |
| D-Ir(L20)₂(CL11) | HTM | EBM | M1:M9:Ir(L20)₂(CL11) | HBM | ETM1:ETM2 |
| | 180 nm | 20 nm | (80%:10%:10%) | 10 nm | (50%:50%) |
| | | | 25 nm | | 30 nm |
| D-Ir(L30)₂(CL12) | HTM | EBM | M1:M4:Ir(L30)₂(CL12) | HBM | ETM1:ETM2 |
| | 180 nm | 20 nm | (80%:5%:10%) | 10 nm | (50%:50%) |
| | | | 25 nm | | 30 nm |
| D-Ir(L1)₂(L25) | HTM | EBM | M1:M4:Ir(L1)₂(L25) | HBM | ETM1:ETM2 |
| | 180 nm | 20 nm | (65%:30%:5%) | 10 nm | (50%:50%) |
| | | | 25 nm | | 30 nm |
| D-Ir(L25)₂(L1) | HTM | EBM | M7:M9:Ir(L25)₂(L1) | HBM | ETM1:ETM2 |
| | 180 nm | 20 nm | (60%:30%:10%) | 10 nm | (50%:50%) |
| | | | 25 nm | | 30 nm |
| D-Ir(L24)₂(L39) | HTM | EBM | M1:Ir(L24)₂(L39) | HBM | ETM1:ETM2 |
| | 180 nm | 20 nm | (90%:10%) | 10 nm | (50%:50%) |
| | | | 25 nm | | 30 nm |

Yellow OLEDs

| | | | | | |
|---|---|---|---|---|---|
| D-Ir(L42)₃ | HTM | — | M3:M2:Ir(L42)₃ | — | ETM1:ETM2 |
| | 230 nm | | (65%:30%:5%) | | (50%:50%) |
| | | | 30 nm | | 30 nm |
| D-Ir(L53)₃ | HTM | — | M3:M2:Ir(L53)₃ | — | ETM1:ETM2 |
| | 230 nm | | (65%:30%:5%) | | (50%:50%) |
| | | | 30 nm | | 30 nm |
| D-Ir(L53)₂(CL2) | HTM | — | M3:M2:Ir(L53)₂(CL2) | — | ETM1:ETM2 |
| | 230 nm | | (65%:30%:5%) | | (50%:50%) |
| | | | 30 nm | | 30 nm |
| D-Ir(L48)₂(CL13) | HTM | — | M3:M2:Ir(L48)₂(CL13) | — | ETM1:ETM2 |
| | 230 nm | | (65%:30%:5%) | | (50%:50%) |
| | | | 30 nm | | 30 nm |
| D-Ir(L53)₂(CL14) | HTM | — | M3:M2:Ir(L53)₂(C14) | — | ETM1:ETM2 |
| | 230 nm | | (65%:30%:5%) | | (50%:50%) |
| | | | 30 nm | | 30 nm |

TABLE 2
Results for the vacuum-processed OLEDs

| | | | | |
|---|---|---|---|---|
| | | | CIE x/y | |
| | EQE (%) | Voltage (V) | 1000 | LT50 (h) |
| Ex. | 1000 cd/m² | 1000 cd/m² | cd/m² | 1000 cd/m² |

Green OLED

| | | | | |
|---|---|---|---|---|
| D-Ir(Ref1)₃ | 21.0 | 3.3 | 0.29/0.58 | 100000 |

Blue OLEDs

| | | | | |
|---|---|---|---|---|
| D-Ir(L1)₃ | 22.3 | 3.5 | 0.15/0.29 | 2500 |
| D-Ir(L6)₃ | 20.7 | 5.5 | 0.15/0.30 | 500 |
| D-Ir(L13)₃ | 20.9 | 4.3 | 0.15/0.30 | — |
| D-Ir(L16)₃ | 16.5 | 4.4 | 0.15/0.23 | — |
| D-Ir(L18)₃ | 21.4 | 3.5 | 0.15/0.28 | — |
| D-Ir(L24)₃ | 17.3 | 4.5 | 0.15/0.23 | — |
| D-Ir(L25)₃ | 23.0 | 3.6 | 0.15/0.28 | — |
| D-Ir(L29)₃ | 21.1 | 4.3 | 0.15/0.30 | 1000 |
| D-Ir(L30)₃ | 21.3 | 4.2 | 0.15/0.30 | — |
| D-Ir(L37)₃ | 19.9 | 4.4 | 0.15/0.33 | — |
| D-Ir(L38)₃ | 19.7 | 4.4 | 0.15/0.32 | — |
| D-Ir(L39)₃ | 19.8 | 3.5 | 0.15/0.33 | — |
| D-Ir(L40)₃ | 20.0 | 4.2 | 0.15/0.32 | 1400 |
| D-Ir(L41)₃ | 20.0 | 4.2 | 0.15/0.32 | — |
| D-Ir(L60)₃ | 21.9 | 4.1 | 0.15/0.31 | 1800 |
| D-Ir(L63)₃ | 20.5 | 4.6 | 0.15/0.30 | — |
| D-Ir(L64)₃ | 21.3 | 4.6 | 0.15/0.28 | 1500 |
| D-Ir(L65)₃ | 21.8 | 4.6 | 0.15/0.28 | 2000 |
| D-Ir(L66)₃ | 22.5 | 4.4 | 0.15/0.34 | 3500 |
| D-Ir(L67)₃ | 22.2 | 4.6 | 0.15/0.28 | 1800 |
| D-Ir(L68)₃ | 21.8 | 4.7 | 0.15/0.29 | 2000 |
| D-Ir(L69)₃ | 21.5 | 4.6 | 0.15/0.28 | — |
| D-Ir(L70)₃ | 22.6 | 4.5 | 0.15/0.31 | 2400 |
| D-Ir(L71)₃ | 20.4 | 4.6 | 0.15/0.29 | — |
| D-Ir(L72)₃ | 21.0 | 4.6 | 0.15/0.29 | — |
| D-Ir(L73)₃ | 18.6 | 4.8 | 0.16/0.34 | — |
| D-Ir(L74)₃ | 21.5 | 4.5 | 0.15/0.29 | 1500 |
| D-Ir(L39)₂(CL1) | 19.5 | 4.8 | 0.16/0.36 | — |
| D-Ir(L1)₂(CL3) | 19.8 | 4.7 | 0.15/0.33 | — |
| D-Ir(L29)₂(CL6) | 18.7 | 5.8 | 0.15/0.28 | — |
| D-Ir(L39)₂(CL6) | 18.0 | 5.6 | 0.15/0.28 | — |
| D-Ir(L1)₂(CL7) | 19.7 | 5.5 | 0.15/0.29 | — |
| D-Ir(L25)₂(CL8) | 20.4 | 5.6 | 0.16/0.34 | — |
| D-Ir(L29)₂(CL9) | 20.2 | 3.7 | 0.15/0.27 | — |
| D-Ir(L39)₂(CL10) | 20.4 | 5.6 | 0.16/0.28 | 800 |
| D-Ir(L6)₂(CL11) | 19.6 | 3.9 | 0.15/0.29 | 1000 |
| D-Ir(L20)₂(CL11) | 19.9 | 4.1 | 0.15/0.29 | — |
| D-Ir(L30)₂(CL12) | 18.4 | 4.7 | 9.15/0.32 | — |
| D-Ir(L1)₂(L25) | 20.8 | 3.6 | 0.15/0.30 | — |
| D-Ir(L25)₂(L1) | 20.2 | 4.5 | 0.15/0.30 | — |
| D-Ir(L24)₂(L39) | 21.2 | 5.6 | 0.15/0.29 | 2000 |

Yellow OLEDs

| | | | | |
|---|---|---|---|---|
| D-Ir(L42)₃ | 19.7 | 3.1 | 0.53/0.45 | — |
| D-Ir(L53)₃ | 21.4 | 3.2 | 0.54/0.43 | 65000 |
| D-Ir(L53)(CL2) | 20.6 | 3.2 | 0.53/0.45 | — |
| D-Ir(L48)(CL13) | 20.8 | 3.3 | 0.51/0.47 | — |
| D-Ir(L50)(CL14) | 17.8 | 3.3 | 0.62/0.36 | 120000 |

### 2) Solution-Processed Devices:

### A: From Soluble Functional Materials

The iridium complexes according to the invention can also be processed from solution, where they result in OLEDs which are significantly simpler as far as the process is concerned, compared with the vacuum-processed OLEDs, with nevertheless good properties. The production of components of this type is based on the production of polymeric light-emitting diodes (PLEDs), which has already been described many times in the literature (for example in WO 2004/037887). The structure is composed of substrate/ITO/PEDOT (80 nm)/interlayer (80 nm)/emission layer (80 nm)/cathode. To this end, use is made of substrates from Technoprint (soda-lime glass), to which the ITO structure (indium tin oxide, a transparent, conductive anode) is applied. The substrates are cleaned with DI water and a detergent (Deconex 15 PF) in a clean room and then activated by a UV/ozone plasma treatment. An 80 nm layer of PEDOT (PEDOT is a polythiophene derivative (Baytron P VAI 4083sp.) from H. C. Starck, Goslar, which is supplied as an aqueous dispersion) is then applied as buffer layer by spin coating, likewise in the clean room. The spin rate required depends on the degree of dilution and the specific spin coater geometry (typically for 80 nm: 4500 rpm). In order to remove residual water from the layer, the substrates are dried by heating on a hotplate at 180° C. for 10 minutes. The interlayer used serves for hole injection, in this case HIL-012 from Merck is used. The interlayer may alternatively also be replaced by one or more layers, which merely have to satisfy the condition of not being detached again by the subsequent processing step of EML deposition from solution. In order to produce the emission layer, the emitters according to the invention are dissolved in toluene together with the matrix materials. The typical solids content of such solutions is between 16 and 25 g/l if, as here, the typical layer thickness of 80 nm for a device is to be achieved by means of spin coating. The solution-processed devices comprise an emission layer comprising A: (polystyrene):M5:M6:Ir(L)₃ (25%:25%:40%:10%) or B: (polystyrene):M5:M9:Ir(L)₃ (25%:50%:20%:5%). The emission layer is applied by spin coating in an inert-gas atmosphere, in the present case argon, and dried by heating at 130° C. for 30 min. Finally, a cathode is applied by vapour deposition of barium (5 nm) and then aluminium (100 nm) (high-purity metals from Aldrich, particularly barium 99.99% (Order No. 474711); vapour-deposition equipment from Lesker, inter alia, typical vapour-deposition pressure 5×10⁻⁶ mbar). Optionally, firstly a hole-blocking layer and then an electron-transport layer and only then the cathode (for example Al or LiF/Al) can be applied by vacuum vapour deposition. In order to protect the device against air and atmospheric moisture, the device is finally encapsulated and then characterised. The OLED examples given have not yet been optimised, Table 3 summarises the data obtained.

TABLE 3
Results with materials rocessed from solution

| | | | | |
|---|---|---|---|---|
| | | EQE (%) | | CIE x/y |
| | Ir(L)₃ | 1000 | Voltage (V) | 1000 |
| Ex. | Device | cd/m² | 1000 cd/m² | cd/m² |

Blue OLEDs

| | | | | |
|---|---|---|---|---|
| S-Ir(L7)₃ | Ir(L7)₃ | 17.3 | 4.6 | 0.15/0.32 |
| | A | | | |
| S-Ir(L9)₃ | Ir(L9)₃ | 16.5 | 4.8 | 0.15/0.32 |
| | B | | | |
| S-Ir(L10)₃ | Ir(L10)₃ | 16.8 | 4.8 | 0.15/0.31 |
| | B | | | |
| S-Ir(L11)₃ | Ir(L11)₃ | 17.0 | 4.7 | 0.15/0.36 |
| | B | | | |
| S-Ir(L12)₃ | Ir(L12)₃ | 16.9 | 4.7 | 0.15/0.33 |
| | B | | | |
| S-Ir(L15)₃ | Ir(L15)₃ | 12.9 | 4.0 | 0.15/0.35 |
| | B | | | |
| S-Ir(L21)₃ | Ir(L21)₃ | 16.7 | 4.6 | 0.15/0.33 |
| | B | | | |
| S-Ir(L22)₃ | Ir(L22)₃ | 17.1 | 4.7 | 0.15/0.33 |
| | B | | | |
| S-Ir(L23)₃ | Ir(L23)₃ | 17.0 | 4.6 | 0.15/0.34 |
| | B | | | |
| S-Ir(L27)₃ | Ir(L27)₃ | 17.3 | 4.7 | 0.15/0.33 |
| | B | | | |
| S-Ir(L31)₃ | Ir(L31)₃ | 17.0 | 4.9 | 0.15/0.33 |
| | B | | | |
| S-Ir(L33)₃ | Ir(L33)₃ | 17.6 | 4.9 | 0.15/0.33 |
| | B | | | |
| S-Ir(L1)₂(CL1) | Ir(L1)₂(CL1) | 16.8 | 4.1 | 0.15/0.33 |
| | B | | | |
| S-Ir(L25)₂(CL1) | Ir(L25)₂(CL1) | 16.9 | 4.3 | 0.15/0.33 |
| | B | | | |
| S-Ir(L13)₂(CL4) | Ir(L13)₂(CL4) | 16.4 | 4.5 | 0.15/0.34 |
| | B | | | |
| S-Ir(L25)₂(L39) | Ir(L25)₂(L39) | 18.4 | 4.7 | 0.15/0.30 |
| | A | | | |

Yellow OLEDs

| | | | | |
|---|---|---|---|---|
| S-Ir(L43)₃ | Ir(L43)₃ | 19.3 | 4.2 | 0.52/0.46 |
| | A | | | |
| S-Ir(L44)₃ | Ir(L44)₃ | 19.0 | 4.4 | 0.53/0.46 |
| | A | | | |
| S-Ir(L46)₃ | Ir(L46)₃ | 18.3 | 4.3 | 0.52/0.45 |
| | A | | | |
| S-Ir(L48)₃ | Ir(L48)₃ | 18.8 | 4.2 | 0.56/0.42 |
| | A | | | |
| S-Ir(L49)₃ | Ir(L48)₃ | 18.4 | 4.3 | 0.56/0.42 |
| | A | | | |
| S-Ir(L50)₃ | Ir(L50)₃ | 19.0 | 4.2 | 0.52/0.46 |
| | A | | | |
| S-Ir(L53)₃ | Ir(L53)₃ | 19.6 | 4.3 | 0.53/0.46 |
| | A | | | |
| S-Ir(L54)₃ | Ir(L54)₃ | 19.5 | 4.2 | 0.55/0.43 |
| | A | | | |
| S-Ir(L42)₂(CL1) | Ir(L42)₂(CL1) | 17.5 | 4.3 | 0.52/0.46 |
| | A | | | |
| S-Ir(L48)₂(CL2) | Ir(L48)₂(CL2) | 17.9 | 4.3 | 0.56/0.42 |
| | A | | | |
| S-Ir(L50)₂(CL2) | Ir(L50)₂(CL2) | 17.8 | 4.3 | 0.51/0.47 |
| | A | | | |
| S-Ir(L50)₂(CL14) | Ir(L50)₂(CL14) | 18.4 | 4.0 | 0.63/0.35 |

### 3) White-Emitting OLEDs

A white-emitting OLED having the following layer structure is produced in accordance with the general process from 1):

TABLE 4
Structure of the white OLEDs

| | | EML | EML | EML | | |
|---|---|---|---|---|---|---|
| | HTL2 | Red | Blue | Green | HBL | ETL |
| Ex. | Thickness | Thickness | Thickness | Thickness | Thickness | Thickness |
| D-W1 | HTM | EBM:Ir-R | M1:M3:Ir(L1)₃ | M3:Ir-G | M3 | ETM1:ETM2 |
| | 230 nm | (97%:3%) | (40%:50%:10%) | (90%:10%) | 10 nm | (50%:50%) |
| | | 9 nm | 8 nm | 7 nm | | 30 nm |

TABLE 5
Device results

| | | | CIE x/y | LT50 |
|---|---|---|---|---|
| | EQE (%) | Voltage (V) | 1000 cd/m² | (h) |
| Ex. | 1000 cd/m² | 1000 cd/m² | CRI | 1000 cd/m² |
| D-W1 | 22.7 | 6.5 | 0.45/0.44 | 4500 |
| | | | 80 | |

```
TABLE 6
Structural formulae of the materials used
  HTM
  EBM
  M1
  M2
  M3
  M4 = HBM
  M5
  M6
  M7
  M8
  M9
  Ir-R
  Ir-G
  ETM1
  ETM2
  D-Ir(Ref1)₃ (in accordance with WO 2011/044988)
```

### Comparison of Thermally Induced Luminescence Quenching:

Polystyrene films are produced alongside one another on a glass specimen slide by applying a drop of a dichloromethane solution of polystyrene and an emitter (solids content of polystyrene about 10% by weight, solids content of emitter about 0.1% by weight) and evaporation of the solvent. The specimen slide is illuminated from above in a darkened room with the light of a UV lamp (commercially available lamp for viewing TLCs, emission wavelength 366 nm), while the stream of hot air from an adjustable hair dryer is directed against it from below. The temperature is increased successively and the thermal luminescence quenching, i.e. the partial or complete quenching of the luminescence, as a function of the temperature is followed with the eye.

Film 1: Polystyrene film comprising the reference emitter Ir-Ref, tris[6-(1,1-dimethylethyl)benzimidazo[1,2-c]quinazolin-1-yl-κC¹,κN¹²]iridium, [1352332-04-7].

Film 2: Polystyrene film comprising emitter Ir(L1)₃ according to the invention

From a hot-air temperature of about 120° C., slow quenching of the photoluminescence of film 1 is evident; the luminescence of film 2 appears unchanged. Above about 180° C., the luminescence of film 1 is substantially extinguished, that of film 2 appears unchanged. Even above about 300° C., only weak extinction of the luminescence of film 2 is observed.

On cooling of the films, the luminescence of both films returns and appears as intense as at the beginning of the experiment. The experiment can be repeated many times, which shows that this is a reversible temperature-dependent extinction phenomenon and not an irreversible decomposition of the samples.

1-14. (canceled)

15. A compound of formula (1):
[Ir(L)ₙ(L′)ₘ] (1)
comprising a moiety Ir(L)ₙ of formula (2):
wherein
Z is on each occurrence CR or N, with the proviso that precisely one Z is N and the other Z is CR;
Y is on each occurrence, identically or differently, CR or N, with the proviso that a maximum of one Y is N, or two adjacent Y together are a group of formula (3):
wherein the dashed bonds denote the linking of this group in the ligand;
X is on each occurrence, identically or differently, CR or N, with the proviso that a maximum of two X per ligand are N;
R is on each occurrence, identically or differently, H, D, F, Cl, Br, I, N(R¹)₂, CN, Si(R¹)₃, B(OR¹)₂, C(═O)R¹, a straight-chain alkyl, alkoxy, or thioalkoxy group having 1 to 40 C atoms or a straight-chain alkenyl or alkynyl group having 2 to 40 C atoms or a branched or cyclic alkyl, alkenyl, alkynyl, alkoxy, or thioalkoxy group having 3 to 40 C atoms, each of which is optionally substituted by one or more radicals R₁, wherein one or more non-adjacent CH₂ groups are optionally replaced by R¹C═CR¹, Si(R¹)₂, C═O, NR¹, O, S, or CONR¹ and wherein one or more H atoms are optionally replaced by D, F, or CN, an aromatic or heteroaromatic ring system having 5 to 60 aromatic ring atoms optionally substituted by one or more radicals R¹, an aryloxy or heteroaryloxy group having 5 to 60 aromatic ring atoms optionally substituted by one or more radicals R¹, or a diarylamino group, diheteroarylamino group, or arylheteroarylamino group having 10 to 40 aromatic ring atoms optionally substituted by one or more radicals R¹; wherein two or more adjacent radicals R optionally define a mono- or polycyclic, aliphatic, aromatic, and/or benzo-fused ring system with one another;
R¹ is on each occurrence, identically or differently, H, D, F, N(R²)₂, CN, Si(R²)₃, B(OR²)₂, C(═O)R², a straight-chain alkyl, alkoxy, or thioalkoxy group having 1 to 40 C atoms or a straight-chain alkenyl or alkynyl group having 2 to 40 C atoms or a branched or cyclic alkyl, alkenyl, alkynyl, alkoxy, or thioalkoxy group having 3 to 40 C atoms, each of which is optionally substituted by one or more radicals R², wherein one or more non-adjacent CH₂ groups are optionally replaced by R²C═CR², Si(R²)₂, C═O, NR², O, S, or CONR² and wherein one or more H atoms are optionally replaced by D, F, or CN, an aromatic or heteroaromatic ring system having 5 to 60 aromatic ring atoms optionally substituted by one or more radicals R², an aryloxy or heteroaryloxy group having 5 to 60 aromatic ring atoms optionally substituted by one or more radicals R², or a diarylamino group, diheteroarylamino group, or arylheteroarylamino group having 10 to 40 aromatic ring atoms optionally substituted by one or more radicals R²; wherein two or more adjacent radicals R¹ optionally define a mono- or polycyclic, aliphatic ring system with one another;
R² is on each occurrence, identically or differently, H, D, F, or an aliphatic, aromatic and/or heteroaromatic organic radical having 1 to 20 C atoms, wherein, one or more H atoms are optionally replaced by D or F; and wherein two or more substituents R² optionally define a mono- or polycyclic, aliphatic, or aromatic ring system with one another;
L′ is, identically or differently on each occurrence, a mono- or bidentate ligand;
n is 1, 2, or 3;
m is 0, 1, 2, 3, or 4.

16. The compound of claim 15, wherein R² is a hydrocarbon radical.

17. The compound of claim 15, wherein n is 3 or wherein n is 2 and m is 1 and L′ is a bidentate ligand coordinated to the iridium via one carbon atom and one nitrogen atom, two oxygen atoms, two nitrogen atoms, one oxygen atom and one nitrogen atom, or one carbon atom and one oxygen atom, or wherein n is 1 and m is 2 and L′ are bidentate ligands coordinated to the iridium via one carbon atom and one nitrogen atom or one carbon atom and one oxygen atom.

18. The compound of claim 15, wherein moiety of formula (2) is selected from the group consisting of the structures of formulae (6a), (6b), (7a), (7b), (8a), and (8b):
wherein
Y is on each occurrence, identically or differently, CR or N.

19. The compound of claim 15, wherein moiety of formula (2) is selected from the group consisting of the structures of formulae (6a-1) to (6b-5), (7a-1) to (7b-7) and (8a-1) to (8b-7):

20. The compound of claim 15, wherein the R bonded to the position adjacent to Z is selected from the group consisting of CF₃, OCF₃, an alkyl or alkoxy group having 1 to 10 C atoms, a dialkylamino group having 2 to 10 C atoms, an aromatic or heteroaromatic ring system, or an aralkyl or heteroaralkyl group and the Z adjacent to the position to which R is bonded is N.

21. The compound of claim 20, wherein R is a branched or cyclic alkyl or alkoxy group having 3 to 10 C atoms.

22. The compound of claim 15, wherein at least one group R bonded to a position adjacent to a N is selected from the group consisting of CF₃, OCF₃, an alkyl or alkoxy group having 1 to 10 C atoms, a dialkylamino group having 2 to 10 C atoms, an aromatic or heteroaromatic ring system or an aralkyl or heteroaralkyl group.

23. The compound of claim 22, wherein R is a branched or cyclic alkyl or alkoxy group having 3 to 10 C atoms.

24. The compound of claim 15, wherein two adjacent Y and/or, if present, two adjacent X in the moiety of formula (2) are each CR and both radicals R, together with the C atoms, define a ring selected from the group consisting of formulae (9), (10), (11), (12), (13), (14), and (15) or, if two radicals R bonded to C atoms bonded directly to one another, together with the C atoms to which they are bonded, define a ring with one another, the ring is selected from the group consisting of formulae (9), (10), (11), (12), (13), (14), and (15):
wherein
a plurality of R¹ are optionally linked to one another so as to define a further ring system;
the dashed bonds indicate the linking of the two carbon atoms in the ligand;
A¹ and A³
are, identically or differently on each occurrence, C(R³)₂, O, S, NR³, or C(═O);
A² is, identically or differently on each occurrence, C(R¹)₂, O, S, NR³, or C(═O); or A²-A² in formulae (10), (11), (13), (14), and (15) optionally, apart from a combination of the above-mentioned groups, is —CR²═CR²— or an ortho-linked arylene or heteroarylene group having 5 to 14 aromatic ring atoms optionally substituted by one or more radicals R²;
G is an alkylene group having 1, 2, or 3 C atoms and is optionally substituted by one or more radicals R², —CR²═CR²—, or an ortho-linked arylene or heteroarylene group having 5 to 14 aromatic ring atoms optionally substituted by one or more radicals R²;
R³ is, identically or differently on each occurrence, F, a straight-chain alkyl or alkoxy group having 1 to 10 C atoms or a branched or cyclic alkyl or alkoxy group having 3 to 10 C atoms, each of which is optionally substituted by one or more radicals R², wherein one or more non-adjacent CH₂ groups are optionally replaced by R²C═CR², Si(R²)₂, C═O, NR², O, S, or CONR² and wherein one or more H atoms are optionally replaced by D or F, an aromatic or heteroaromatic ring system having 5 to 24 aromatic ring atoms optionally substituted by one or more radicals R², an aryloxy or heteroaryloxy group having 5 to 24 aromatic ring atoms, optionally substituted by one or more radicals R², or an aralkyl or heteroaralkyl group having 5 to 24 aromatic ring atoms optionally substituted by one or more radicals R²; wherein two radicals R³ bonded to the same carbon atom optionally define an aliphatic or aromatic ring system with one another so as to define a Spiro system; and wherein R³ optionally defines an aliphatic ring system with an adjacent radical R or R¹;
with the proviso that two heteroatoms in these groups are not bonded directly to one another and two groups C═O are not bonded directly to one another.

25. The compound of claim 15, wherein the moiety of formula (2) comprises one or more radicals R selected on each occurrence, identically or differently, from the group consisting of H, D, F, N(R¹)₂, CN, Si(R¹)₃, C(═O)R¹, a straight-chain alkyl group having 1 to 10 C atoms or an alkenyl group having 2 to 10 C atoms or a branched or cyclic alkyl group having 3 to 10 C atoms, each of which is optionally substituted by one or more radicals R¹, wherein one or more H atoms are optionally replaced by D or F, or an aromatic or heteroaromatic ring system having 5 to 24 aromatic ring atoms optionally substituted by one or more radicals R¹; wherein two adjacent radicals R or R with R¹ optionally a mono- or polycyclic, aliphatic or aromatic ring system with one another.

26. The compound of claim 15, wherein L′ is selected from the group consisting of carbon monoxide, nitrogen monoxide, alkyl cyanides, aryl cyanides, alkyl isocyanides, aryl isocyanides, amines, phosphines, phosphites, arsines, stibines, nitrogen-containing heterocycles, carbenes, hydride, deuteride, F⁻, Cl⁻, Br⁻, I⁻, alkylacetylides, arylacetylides, cyanide, cyanate, isocyanate, thiocyanate, isothiocyanate, aliphatic and aromatic alcoholates, aliphatic and aromatic thioalcoholates, amides, carboxylates, aryl groups, O²⁻, S²⁻, carbides, nitrenes, diamines, imines, 1,3-diketonates derived from 1,3-diketones, 3-ketonates derived from 3-ketoesters, carboxylates derived from aminocarboxylic acids, salicyliminates, dialcoholates, dithiolates, and bidentate monoanionic ligands which form with the iridium a cyclometallated five-membered ring or six-membered ring having at least one iridium-carbon bond.

27. A process for preparing the compound of claim 15 comprising reacting the free ligand L with iridium alkoxides of formula (44), with iridium ketoketonates of formula (45), with iridium halides of formula (46), with dimeric iridium complexes of the formula (47) or (48), or with iridium compounds which carry both alkoxide and/or halide and/or hydroxyl and also ketoketonate radicals:
wherein
Hal is F, Cl, Br, or I.

28. A formulation comprising at least one compound of claim 15 and at least one further compound.

29. The formulation of claim 28, wherein the at least one further compound is a solvent or a mixture of a plurality of solvents.

30. An oxygen sensor comprising the compound of claim 15.

31. An electronic device comprising the compound of claim 15.

32. The electronic device of claim 31, wherein the electronic device is selected from the group consisting of organic electroluminescent devices, organic integrated circuits, organic field-effect transistors, organic thin-film transistors, organic light-emitting transistors, organic solar cells, organic optical detectors, organic photoreceptors, organic field-quench devices, light-emitting electrochemical cells, and organic laser diodes.

33. The electronic device of claim 32, wherein the electronic device is an organic electroluminescent device and the compound is employed as emitting compound in one or more emitting layers.

34. The electronic device of claim 33, wherein the emitting layer comprises one or more matrix materials selected from the group consisting of ketones, phosphine oxides, sulfoxides, sulfones, triarylamines, carbazoles, indolocarbazoles, indenocarbazoles, azacarbazoles, bipolar matrix materials, silanes, azaboroles, boronic esters, diazasiloles, diazaphospholes, triazines, zinc complexes, beryllium complexes, dibenzofurans, and bridged carbazoles.
